(19) United States
(12) Patent Application Publication
(10) Pub. No.: US 2009/0197206 A1
(43) Pub. Date: Aug. 6, 2009

(54) METHOD OF MAKING IMAGES USING FRESH PROCESSING SOLUTION

(76) Inventors: Kevin B. Ray, Fort Collins, CO (US); Anthony P. Kitson, Greeley, CO (US)

Correspondence Address: Andrew J. Anderson;Patent Legal Staff, Eastman Kodak Company, 343 State Street, Rochester, NY, 14650-2201, US

(21) Appl. No.: 12/019,681

(22) Filed: Jan. 25, 2008

(51) Int. Cl. G03F 7/12

(52) U.S. Cl. 430/302

(57) ABSTRACT

A method for providing lithographic printing plates is achieved by imaging a lithographic printing plate precursor and processing it with fresh (not reused) samples of a processing solution that both develops and protects the resulting lithographic image. The lithographic printing plate precursors can be either negative-working or positive-working.

### FIELD OF THE INVENTION

This invention provides a method for preparing images in one or more imageable elements such as positive-working and negative-working lithographic printing plate precursors. Each imaged element is processed using a fresh sample of a processing solution that is not reused. The processing solution both develops and protects the imaged surface before the imaged element is used in lithographic printing.

### BACKGROUND OF THE INVENTION

In conventional or “wet” lithographic printing, ink receptive regions, known as image areas, are generated on a hydrophilic surface. When the surface is moistened with water and ink is applied, the hydrophilic regions retain the water and repel the ink, and the ink receptive regions accept the ink and repel the water. The ink is transferred to the surface of a material upon which the image is to be reproduced. For example, the ink can be first transferred to an intermediate blanket that in turn is used to transfer the ink to the surface of the material upon which the image is to be reproduced.

Imageable elements useful to prepare lithographic printing plates typically comprise at least one imageable layer applied over the hydrophilic surface of a substrate. The imageable layer(s) include one or more radiation-sensitive components that can be dispersed in a suitable binder. Alternatively, the radiation-sensitive component can also be the binder material. Following imaging, either the imaged regions or the non-imaged regions of the imageable layer are removed by a suitable developer, revealing the underlying hydrophilic surface of the substrate. If the imaged (exposed) regions are removed, the element is considered as positive-working. Conversely, if the non-imaged (non-exposed) regions are removed, the element is considered as negative-working. In each instance, the regions of the imageable layer (that is, the image areas) that remain are ink-receptive, and the regions of the hydrophilic surface revealed by the developing process accept water or a fountain solution and repel ink.

Direct digital imaging has become increasingly important in the printing industry. Imageable elements for the preparation of lithographic printing plates have been developed for use with infrared lasers. Thermally imageable, multi-layer positive-working elements containing polymeric binders that become soluble in alkaline developers after imaging are described in many patents. Some of these positive-working thermally imageable elements are developed (processed) using low pH developers when the outer layers include novolak resins and dissolution suppressing agents.

Typically, both negative-working and positive-working lithographic printing plate precursors are used to provide lithographic printing plates by imaging, developing, rinsing, and “gumming” (using a finisher gum). Development is usually carried out using a solvent-containing or highly alkaline, silicate-containing solution to remove coating to reveal the hydrophilic aluminum-containing substrate that repels ink and attracts water. The gumming provides a protective layer over exposed and non-exposed regions and especially over the revealed substrate.

Single-use highly alkaline or solvent-containing developers may be used to improve consistency in development as described in U.S. Pat. 6,992,688 (Shimazu et al.).

Development of negative-working elements using gums is described for example, in EP Publications 1,751,625 (Van Damme et al. published as WO 2005/111727) 1,788,429 (Loccufier et al. et al.), 1,788,430 (Williamson et al.), 1,788,431 (Van Damme et al.), 1,788,434 (Van Damme et al.), 1,788,441 (Van Damme), 1,788,442 (Van Damme), 1,788,443 (Van Damme), 1,788,444 (Van Damme), and 1,788,450 (Van Damme), and WO 2007/057442 (Gries et al.) and WO 2007/060200 (Andriessen et al.).

Simple processing (development) of imaged elements has become a goal of workers in the lithographic art. For example, copending and commonly assigned U.S. Ser. No. 11/872,772 that was filed Oct. 16, 2007 by K. Ray, Tao, Miller, Clark, and Roth) describes negative-working imageable elements that are sensitive to infrared radiation and can be simply processed (developed and “gummed”) using finishing gum solutions without the need for a conventional alkaline developer. This reduces the amount of processing equipment that is needed, costs, and consumption of processing solution.

In addition, copending and commonly assigned U.S. Ser. No. 11/947,817 (filed Dec. 4, 2007 by K. Ray, Tao, and Clark) describes the use of gums to develop imaged UV-sensitive, negative-working imageable elements that contain specific nonpolymeric diamide additives.

Copending and commonly assigned U.S. Ser. No. 12/017,408 (filed Jan. 22, 2008 by K. Ray and Kitson, Docket 94546/JLT) describes the use of a single non-silicate processing solution to both develop and protect images in imaged positive-working lithographic printing plate precursors.

U.S. Pat. No. 4,179,208 (Martino) describes a processing machine that uses an alkaline developer that is modified by the addition of a small amount of “gum”, and the developer is re-used or replenished but there are no details about the composition of this modified developer.

### Problem to be Solved

As noted above, known processing methods using traditional alkaline development followed by gumming have a number of problems that are addressed by the use of “simple” processing methods using a gum-like processing solution. Yet, while the processing methods described in the noted art represent important advances in the technology, there are additional problems to overcome. As the processing cycle proceeds when using a gum (such as a finishing gum) as the only processing solution, the residue of chemicals removed during processing builds up in the processing solution. Since that processing solution is designed to both develop the imaged element and to protect the resulting image and especially the revealed aluminum-containing substrate, the increasing contamination in the processing solution leaves contaminants (debris) on the substrate, leading to printing problems such as poor water acceptable or ink repellency and undesirable blanket toning.

There is a need to provide “simple” methods using gum processing solutions for both positive-working and negative-working lithographic printing plate precursors that avoid the noted problems.

### SUMMARY OF THE INVENTION

This invention provides a method for making an image comprising:

A) imagewise exposing a lithographic printing plate precursor comprising a substrate that has a hydrophilic surface using infrared radiation to provide both exposed and non-exposed regions in the imaged precursor, the lithographic printing plate precursor further comprising an infrared radiation absorbing compound, and

B) applying a fresh sample of a processing solution having a pH of from about 6 to about 11 to the imaged precursor both: (1) to remove predominantly only either the exposed regions or the non-exposed regions, and (2) to provide a protective coating over all of the exposed and non-exposed regions of the resulting imaged lithographic printing plate, and that fresh sample of processing solution is not reused.

This invention also provides a method of making multiple lithographic printing plates comprising:

A) imagewise exposing a first lithographic printing plate precursor comprising a substrate that has a hydrophilic surface using infrared radiation to provide both exposed and non-exposed regions in the imaged precursor,

B) applying a fresh sample of a processing solution having a pH of from about 6 to about 11 to the imaged precursor both: (1) to remove predominantly only either said exposed or non-exposed regions, and (2) to provide a protective coating over all of the exposed and non-exposed regions of the resulting first imaged lithographic printing plate, and the fresh sample of processing solution is not reused, and

C′) repeating steps A and B using additional fresh samples of the same processing solution in step B for each of one or more additional lithographic printing plate precursors, which fresh samples are not reused.

Thus, the one or more additional lithographic printing plate precursors can be the same or different as the first lithographic printing plate precursor.

For example, the first and one or more additional lithographic printing plate precursors processed according to this invention can have essentially the same aluminum-containing substrate and layer composition(s), and these multiple lithographic printing plate precursors can be either negative-working, positive-working, or both.

The fresh sample of processing solution used in the practice of this invention performs a dual function of development and protecting the developed surface. The lithographic printing plates thus prepared can be used right away for lithographic printing without any need to rinse off excess processing solution. This simpler and essentially one-step processing method provides advantages in work-flow and productivity for preparing the printing plates for use in the pressroom. Because a fresh sample of the processing solution is used for each processed precursor, there is less contamination of the resulting printing plate surfaces and more consistency in the image and printing results. All of these advantages further reduce costs of processing as well.

A further advantage of this invention is that the processor can be modified to introduce fresh samples of different processing solutions for different multiple imaged precursors that are processed in the same apparatus. For example, a series of imaged negative-working lithographic printing plate precursors can be processed in sequence with individual fresh samples of processing solutions, followed by processing of one or more positive-working lithographic printing plate precursors in sequence using a fresh sample of a different processing solution according to this invention.

For example, a method of making multiple lithographic printing plates comprises:

A) imagewise exposing a one or more lithographic printing plate precursors each comprising a substrate that has a hydrophilic surface using infrared radiation to provide both exposed and non-exposed regions in the one or more imaged precursors,

B) applying to each imaged precursor, a fresh sample of the same processing solution having a pH of from about 6 to about 11 to the imaged precursor both: (1) to remove predominantly only either the exposed or non-exposed regions, and (2) to provide a protective coating over all of the exposed and non-exposed regions of the resulting first imaged lithographic printing plate, and each of the fresh samples of processing solution are not reused,

C″) repeating steps A and B using a fresh sample of a different processing solution defined in step B for each of one or more additional lithographic printing plate precursors that are different than the one or more precursors defined in A, which fresh samples are not reused.

Thus, the one or more lithographic printing plate precursors imaged and processed in steps A and B can be negative-working lithographic printing plate precursors, and the one or more additional lithographic printing plate precursors imaged and processed in step C″ can be positive-working lithographic printing plate precursors, or

the one or more lithographic printing plate precursors imaged and processed in steps A and B can be positive-working lithographic printing plate precursors, and the one or more additional lithographic printing plate precursors imaged and processed in step C″ can be negative-working lithographic printing plate precursors.

In addition, this invention provides a method of lithographic printing comprising:

A) imagewise exposing a lithographic printing plate precursor comprising a substrate that has a hydrophilic surface using infrared radiation to provide both exposed and non-exposed regions in the imaged precursor,

the lithographic printing plate precursor further comprising an infrared radiation absorbing compound,

B) applying a fresh sample of a processing solution having a pH of from about 6 to about 11 to the imaged precursor both: (1) to remove predominantly only either the exposed regions or the non-exposed regions, and (2) to provide a protective coating over all of the exposed and non-exposed regions of the resulting imaged lithographic printing plate, and the fresh sample of processing solution is not reused,

C) removing excess processing solution from the imaged lithographic printing plate, with optional drying, and

D) contacting the imaged lithographic printing plate with a lithographic printing ink, fountain solution, or both.

### DETAILED DESCRIPTION OF THE INVENTION

### Definitions

Unless the context indicates otherwise, when used herein, the terms “imageable element”, “positive-working lithographic printing plate precursor”, and “negative-working lithographic printing plate precursor” are meant to be references to embodiments useful in the practice of the present invention. Unless otherwise noted the term “precursor” refers to both negative-working or positive-working lithographic printing plate precursors that are sometimes known in the art generally as “imageable elements”.

In addition, unless the context indicates otherwise, the various components described herein such as “first polymeric binder”, “second polymeric binder”, “anionic surfactant”, “radiation absorbing compound”, “IR dye”, “free radically polymerizable component”, “initiator”, and similar terms also refer to mixtures of such components. Thus, the use of the article “a” or “an” is not necessarily meant to refer to only a single component.

By “multilayer” imageable element, we mean a positive-working imageable element such as a lithographic printing plate that has at least two imageable layers required for providing an image, for example, “inner” and “outer” layers as described below. However, such elements may comprise additional non-imaging layers on either side of the substrate.

By “single-layer” imageable element, we mean a positive-working or negative-working imageable element having only one layer needed for imaging, but such elements may comprise additional non-imaging layers on either side of the substrate (such as a topcoat over an imageable layer in negative-working imageable elements).

By “processing”, we mean that the fresh sample of a single processing solution is used to both develop the imaged precursor and to protect the image prior to the printing operation.

By the term “fresh sample of processing solution” we mean a processing solution that has not been previously used for its intended purpose, nor is this fresh sample reused.

By the term “remove predominantly only said exposed regions” during development, we mean that the exposed regions of the outer layer and the corresponding regions of any underlying layers are selectively and preferentially removed by the processing solution, but not the non-exposed regions to any significant extent (there may be insubstantial removal of the non-exposed regions).

By the term “remove predominantly only said non-exposed regions” during development, we mean that the non-exposed regions of the imageable layer and the corresponding regions of any underlying layers are selectively and preferentially removed by the processing solution, but not the exposed regions to any significant extent (there may be insubstantial removal of the exposed regions).

By “computer-to-press”, we mean the imaging means is carried out using a computer-directed imaging means (such as a laser) directly to the imageable layers without using masking or other intermediate imaging films.

Unless otherwise indicated, the term “processing solution” is meant to refer to the slightly acidic to slightly alkaline solutions described herein that are used to carry out the processing step B) of the method of this invention.

Unless otherwise indicated, percentages refer to percents by dry weight, either the dry solids of a layer composition or formulation, or the dry coated weight of a layer. Unless otherwise indicated, the weight percent values can be interpreted as for either a layer formulation or a dried layer coating.

For clarification of definitions for any terms relating to polymers, reference should be made to “Glossary of Basic Terms in Polymer Science” as published by the International Union of Pure and Applied Chemistry (“IUPAC”), Pure Appl. Chem. 68, 2287-2311 (1996). However, any definitions explicitly set forth herein should be regarded as controlling.

Unless otherwise indicated, the term “polymer” refers to high and low molecular weight polymers including oligomers and includes homopolymers and copolymers.

The term “copolymer” refers to polymers that are derived from two or more different monomers. That is, they comprise recurring units having at least two different chemical structures.

The term “backbone” refers to the chain of atoms in a polymer to which a plurality of pendant groups can be attached. An example of such a backbone is an “all carbon” backbone obtained from the polymerization of one or more ethylenically unsaturated polymerizable monomers. However, other backbones can include heteroatoms wherein the polymer is formed by a condensation reaction or some other means.

### Uses

The method of this invention is used primarily to provide lithographic printing plates that can be used in lithographic printing operations as described in more detail below.

In general, the positive-working or negative-working lithographic printing plate precursors comprise a substrate having one or more imageable layers disposed thereon. The following general discussion of both negative-working and positive-working imageable compositions and elements is meant to be representative of the most likely embodiments used in the practice of this invention, and is not meant to be limiting since a skilled worker would know how to modify the elements in view of what is known in the prior art to provide additional embodiments.

### Substrates

This discussion about substrates is considered generic to their use in either negative-working or positive-working lithographic printing plate precursors described herein. However, a skilled worker in the art would understand that there may be preferences of substrates for specific types of precursors to achieved desired adhesion to overlying layers and imaging and development properties.

This substrate can be an untreated or uncoated support but it is usually treated or coated in various ways as described below to provide a highly hydrophilic surface prior to application of a layer composition. The substrate comprises a support that can be composed of any material that is conventionally used to prepare lithographic printing plate precursors. The substrate can be treated to provide an “interlayer” for improved adhesion or hydrophilicity, and the inner layer formulation is applied over the interlayer.

The substrate is usually in the form of a sheet, film, or foil, and is strong, stable, and flexible and resistant to dimensional change under conditions of use so that color records will register a full-color image. Typically, the support can be any self-supporting material including polymeric films (such as polyester, polyethylene, polycarbonate, cellulose ester polymer, and polystyrene films), glass, ceramics, metal sheets or foils, or stiff papers (including resin-coated and metallized papers), or a lamination of any of these materials (such as a lamination of an aluminum foil onto a polyester film). Metal supports include sheets or foils of aluminum, copper, zinc, titanium, and alloys thereof.

Polymeric film supports may be modified on one or both surfaces with a “subbing” layer to enhance hydrophilicity, or paper supports may be similarly coated to enhance planarity. Examples of subbing layer materials include but are not limited to, alkoxysilanes, amino-propyltriethoxysilanes, glycidioxypropyl-triethoxysilanes, and epoxy functional polymers, as well as conventional hydrophilic subbing materials used in silver halide photographic films (such as gelatin and other naturally occurring and synthetic hydrophilic colloids and vinyl polymers including vinylidene chloride copolymers).

A useful substrate is composed of an aluminum-containing support that may be coated or treated using techniques known in the art, including physical graining, electrochemical graining, chemical graining, and anodizing. For example, the aluminum sheet can be anodized using phosphonic acid or sulfuric acid using conventional procedures.

An optional interlayer may be formed by treatment of the aluminum support with, for example, a silicate, dextrine, calcium zirconium fluoride, hexafluorosilicic acid, phosphate/fluoride, poly(vinyl phosphonic acid) (PVPA), vinyl phosphonic acid-acrylic acid copolymer, poly(acrylic acid), or (meth)acrylic acid copolymer, or mixtures thereof. For example, the grained and/or anodized aluminum support can be treated with poly(phosphonic acid) using known procedures to improve surface hydrophilicity to provide a lithographic hydrophilic substrate.

The thickness of the substrate can be varied but should be sufficient to sustain the wear from printing and thin enough to wrap around a printing form. Such embodiments typically include a treated aluminum foil having a thickness of from about 100 to about 600 μm.

The backside (non-imaging side) of the substrate may be coated with antistatic agents and/or slipping layers or a matte layer to improve handling and “feel” of the imageable element.

The substrate can also be a cylindrical surface having the imageable layers applied thereon, and thus be an integral part of the printing press or a sleeve that is incorporated onto a press cylinder. The use of such imaged cylinders is described for example in U.S. Pat. No. 5,713,287 (Gelbart).

### Negative-Working Lithographic Printing Plate Precursors

Some embodiments useful in this invention are negative-working imageable elements or negative-working lithographic printing plate precursors that have a single imageable layer containing a radiation-sensitive composition that comprises:

a radically polymerizable component,

an initiator composition capable of generating free radicals sufficient to initiate polymerization of free radically polymerizable groups upon exposure to imaging radiation,

a radiation absorbing compound, and

a polymeric binder.

The radiation-sensitive composition (and imageable layer) includes one or more free radically polymerizable components, each of which contains one or more free radically polymerizable groups that can be polymerized using free radical initiation. For example, such free radically polymerizable components can contain one or more free radical polymerizable monomers or oligomers having one or more addition polymerizable ethylenically unsaturated groups, crosslinkable ethylenically unsaturated groups, ring-opening polymerizable groups, azido groups, aryldiazonium salt groups, aryldiazosulfonate groups, or a combination thereof. Similarly, crosslinkable polymers having such free radically polymerizable groups can also be used.

Suitable ethylenically unsaturated components that can be polymerized or crosslinked include ethylenically unsaturated polymerizable monomers that have one or more of the polymerizable groups, including unsaturated esters of alcohols, such as acrylate and methacrylate esters of polyols. Oligomers and/or prepolymers, such as urethane acrylates and methacrylates, epoxide acrylates and methacrylates, polyester acrylates and methacrylates, polyether acrylates and methacrylates, and unsaturated polyester resins can also be used. In some embodiments, the free radically polymerizable component comprises carboxy groups.

Useful free radically polymerizable components include free-radical polymerizable monomers or oligomers that comprise addition polymerizable ethylenically unsaturated groups including multiple acrylate and methacrylate groups and combinations thereof, or free-radical crosslinkable polymers. Free radically polymerizable compounds include those derived from urea urethane (meth)acrylates or urethane (meth)acrylates having multiple polymerizable groups. For example, a free radically polymerizable component can be prepared by reacting DESMODUR® N100 aliphatic polyisocyanate resin based on hexamethylene diisocyanate (Bayer Corp., Milford, Conn.) with hydroxyethyl acrylate and pentaerythritol triacrylate. Useful free radically polymerizable compounds include NK Ester A-DPH (dipentaerythritol hexaacrylate) that is available from Kowa American, and Sartomer 399 (dipentaerythritol pentaacrylate), Sartomer 355 (di-trimethylolpropane tetraacrylate), Sartomer 295 (pentaerythritol tetraacrylate), and Sartomer 415 [ethoxylated (20)trimethylolpropane triacrylate] that are available from Sartomer Company, Inc.

The free radically polymerizable component can also be one or more of the non-polymeric components that have 1H-tetrazole groups and are also polymerizable in the presence of free radicals. Such components generally are mono-, di-, or triacrylates, or they are styryl compounds to which the 1H-tetrazole groups are attached. There can be multiple free radically polymerizable components present in the radiation-sensitive composition.

Numerous other free radically polymerizable components are known to those skilled in the art and are described in considerable literature including Photoreactive Polymers: The Science and Technology of Resists, A Reiser, Wiley, New York, 1989, pp. 102-177, by B. M. Monroe in Radiation Curing: Science and Technology, S. P. Pappas, Ed., Plenum, New York, 1992, pp. 399-440, and in “Polymer Imaging” by A. B. Cohen and P. Walker, in Imaging Processes and Material, J. M. Sturge et al. (Eds.), Van Nostrand Reinhold, New York, 1989, pp. 226-262. For example, useful free radically polymerizable components are also described in EP 1,1 82,033A1 (Fujimaki et al.), beginning with paragraph [0170], and in U.S. Pat. No. 6,309,792 (Hauck et al.), U.S. Pat. No. 6,569,603 (Furukawa), and U.S. Pat. No. 6,893,797 (Munnelly et al.). The free radically polymerizable component can also include carboxy groups as described for example in U.S. Pat. No. 7,153,632 (Saraiya et al.).

The one or more free radically polymerizable components (monomeric, oligomeric, or polymeric) can be present in the radiation-sensitive composition or imageable layer in an amount of at least 10 weight % and up to 70 weight %, and typically from about 20 to about 50 weight %, based on the total dry weight. The weight ratio of the free radically polymerizable component to the total polymeric binders (described below) is generally from about 5:95 to about 95:5, and typically from about 10:90 to about 90:10, or even from about 30:70 to about 70:30.

The radiation-sensitive composition (and imageable layer) also includes an initiator composition that is capable of generating free radicals sufficient to initiate polymerization of all the various free radically polymerizable components upon exposure of the composition to imaging infrared radiation. The initiator composition is generally responsive to imaging infrared or near-IR radiation corresponding to the spectral range of at least 700 nm and up to and including 1400 nm. Initiator compositions are used that are appropriate for the desired imaging wavelength(s). More typically, they are responsive to radiation at a wavelength of at least 700 nm and up to and including 1200 nm.

Useful IR-sensitive radiation-sensitive compositions include an onium salt including but not limited to, a sulfonium, oxysulfoxonium, oxysulfonium, sulfoxonium, ammonium, selenonium, arsonium, phosphonium, diazonium, or halonium salt. Further details of useful onium salts, including representative examples, are provided in U.S. Patent Application Publication 2002/0068241 (Oohashi et al.), WO 2004/101280 (Munnelly et al.), and U.S. Pat. No. 5,086,086 (Brown-Wensley et al.), U.S. Pat. No. 5,965,319 (Kobayashi), and U.S. Pat. No. 6,051,366 (Baumann et al.). For example, suitable phosphonium salts include positive-charged hypervalent phosphorus atoms with four organic substituents. Suitable sulfonium salts such as triphenylsulfonium salts include a positively-charged hypervalent sulfur with three organic substituents. Suitable diazonium salts possess a positive-charged azo group (that is —N═N¹). Suitable ammonium salts include a positively-charged nitrogen atom such as substituted quaternary ammonium salts with four organic substituents, and quaternary nitrogen heterocyclic rings such as N-alkoxypyridinium salts. Suitable halonium salts include a positively-charged hypervalent halogen atom with two organic substituents. The onium salts generally include a suitable number of negatively-charged counterions such as halides, hexafluorophosphate, thiosulfate, hexafluoroantimonate, tetrafluoroborate, sulfonates, hydroxide, perchlorate, n-butyltriphenyl borate, tetraphenyl borate, and others readily apparent to one skilled in the art.

The halonium salts are useful such as the iodonium salts. In one embodiment, the onium salt has a positively-charged iodonium, (4-methylphenyl)[4-(2-methylpropyl)phenyl]-moiety and a suitable negatively charged counterion. Typically anions for the iodonium initiators are chloride, bromide, nitrate, perchlorate, hexafluorophosphate, tetrafluoroboate, tetraphenylborate, and triphenylbutylborate anions. A representative example of such an iodonium salt is available as Irgacure® 250 from Ciba Specialty Chemicals (Tarrytown, N.Y.) that is (4-methylphenyl)[4-(2-methylpropyl)phenyl]iodonium hexafluorophosphate and is supplied in a 75% propylene carbonate solution.

Useful boron-containing compounds include organic boron salts that include an organic boron anion such as those described in U.S. Pat. No. 6,569,603 (Furukawa) that is paired with a suitable cation such as an alkali metal ion, an onium, or a cationic sensitizing dye. Useful onium cations for this purpose include but are not limited to, ammonium, sulfonium, phosphonium, iodonium, and diazonium cations. They may be used alone or in combination with various co-initiators such as heterocyclic mercapto compounds including mercaptotriazoles, mercaptobenzimidazoles, mercaptobenzoxazoles, mercaptobenzothiazoles, mercaptobenzoxadiazoles, mercaptotetrazoles, such as those described for example in U.S. Pat. No. 6,884,568 (Timpe et al.) in amounts of at least 0.5 and up to and including 10 weight % based on the total solids of the radiation-sensitive composition. Useful mercaptotriazoles include 3-mercapto-1,2,4-triazole, 4-methyl-3-mercapto-1,2,4-triazole, 5-mercapto-1-phenyl-1,2,4-triazole, 4-amino-3-mercapto-1,2,4,-triazole, 3-mercapto-1,5-diphenyl-1,2,4-triazole, and 5-(p-aminophenyl)-3-mercapto-1,2,4-triazole.

Other useful initiator compositions include one or more azine compounds as described for example in U.S. Pat. No. 6,936,384 (Munnelly et al.). These compounds are organic heterocyclic compounds containing a 6-membered ring formed from carbon and nitrogen atoms. Azine compounds include heterocyclic groups such as pyridine, diazine, and triazine groups, as well as polycyclic compounds having a pyridine, diazine, or triazine substituent fused to one or more aromatic rings such as carbocyclic aromatic rings. Thus, the azine compounds include, for example, compounds having a quinoline, isoquinoline, benzodiazine, or naphthodiazine substituent. Both monocyclic and polycyclic azine compounds are useful.

Useful azine compounds are triazine compounds that include a 6-membered ring containing 3 carbon atoms and 3 nitrogen atoms such as those described in U.S. Pat. No. 6,309,792 (Hauck et al.), U.S. Pat. No. 6.010,824 (Komano et al.), U.S. Pat. No. 5,885,746 (Iwai et al), U.S. Pat. No. 5,496,903 (Watanabe et al.), and U.S. Pat. No. 5,219,709 (Nagasaka et al.).

The azinium form of azine compounds can also be used if desired. In azinium compounds, a quaternizing substituent of a nitrogen atom in the azine ring is capable of being released as a free radical. The alkoxy substituent that quaternizes a ring nitrogen atom of the azinium nucleus can be selected from among a variety of alkoxy substituents.

Halomethyl-substituted triazines, such as trihalomethyl triazines, are useful in the initiator composition. Representative compounds of this type include but are not limited to, 1,3,5-triazine derivatives such as those having 1 to 3-CX₃ groups wherein X independently represent chlorine or bromine atoms, including polyhalomethyl-substituted triazines and other triazines, such as 2,4-trichloromethyl-6-methoxyphenyl triazine, 2-phenyl-4,6-bis(trichloromethyl)-s-triazine, 2,4,6-tris(trichloromethyl)-s-triazine, 2-methyl-4,6-bis(trichloromethyl)-s-triazine, 2-(styryl-4,6-bis(trichloromethyl)-s-triazine, 2-(p-methoxystyryl)-4,6-bis(trichloromethyl)-s-triazine, 2-(4-methoxy-naphtho-1-yl)-4,6-bis(trichloromethyl)-s-triazine, 2-(4-ethoxynaphtho-1yl)-4,6-bis(trichloromethyl)-s-triazine, and 2-(4-(2-ethoxyethyl)-naphtho-1-yl)-4,6-bis(trichloromethyl)-s-triazine], 2-(4-methylthiophenyl)-4,6-bis(trichloromethyl)-2-triazine, 2-(4-chlorophenyl-4,6-bis(trichloromethyl)-2-triazine, 2,4,6-tri(trichloromethyl)-2-triazine, and 2,4,6-tri(tribromomethyl)-2-triazine.

The azine compounds may be used alone or in combination with one or more co-initiators such as titanocenes, mono- and polycarboxylic acids, hexaarylbisimidazoles, as described for example in U.S. Pat. No. 4,997,745 (Kawamura et al.).

Useful iodonium cations are well known in the art including but not limited to, those described in U.S. Patent Application Publication 2002/0068241 (Oohashi et al.), WO 2004/101280 (Munnelly et al.), and U.S. Pat. No. 5,086,086 (Brown-Wensley et al.), U.S. Pat. No. 5,965,319 (Kobayashi), and U.S. Pat. No. 6,051,366 (Baumann et al.). For example, a useful iodonium cation includes a positively charged iodonium, (4-methylphenyl)[4-(2-methylpropyl)phenyl]-moiety and a suitable negatively charged borate counterion.

Useful diaryliodonium borates include, but are not limited to, those represented by the following Structure (IB):

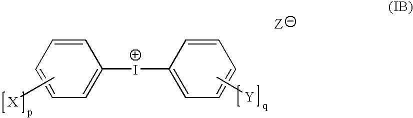

wherein X and Y are independently halo groups (for example, fluoro, chloro, or bromo), substituted or unsubstituted alkyl groups having 1 to 20 carbon atoms (for example, methyl, chloromethyl, ethyl, 2-methoxyethyl, n-propyl, isopropyl, isobutyl, n-butyl, t-butyl, all branched and linear pentyl groups, 1-ethylpentyl, 4-methylpentyl, all hexyl isomers, all octyl isomers, benzyl, 4-methoxybenzyl, p-methylbenzyl, all dodecyl isomers, all icosyl isomers, and substituted or unsubstituted mono-and poly-, branched and linear haloalkyls), substituted or unsubstituted alkyloxy having 1 to 20 carbon atoms (for example, substituted or unsubstituted methoxy, ethoxy, iso-propoxy, t-butoxy, (2-hydroxytetradecyl)oxy, and various other linear and branched alkyleneoxyalkoxy groups), substituted or unsubstituted aryl groups having 6 or 10 carbon atoms in the carbocyclic aromatic ring (such as substituted or unsubstituted phenyl and naphthyl groups including mono- and polyhalophenyl and naphthyl groups), or substituted or unsubstituted cycloalkyl groups having 3 to 8 carbon atoms in the ring structure (for example, substituted or unsubstituted cyclopropyl, cyclopentyl, cyclohexyl, 4-methylcyclohexyl, and cyclooctyl groups). Typically, X and Y are independently substituted or unsubstituted alkyl groups having 1 to 8 carbon atoms, alkyloxy groups having 1 to 8 carbon atoms, or cycloalkyl groups having 5 or 6 carbon atoms in the ring, and more preferably, X and Y are independently substituted or unsubstituted alkyl groups having 3 to 6 carbon atoms (and particularly branched alkyl groups having 3 to 6 carbon atoms). Thus, X and Y can be the same or different groups, the various X groups can be the same or different groups, and the various Y groups can be the same or different groups. Both “symmetric” and “asymmetric” diaryliodonium borate compounds are contemplated but the “symmetric” compounds (that is, they have the same groups on both phenyl rings) are useful.

In addition, two or more adjacent X or Y groups can be combined to form a fused carbocyclic or heterocyclic ring with the respective phenyl groups.

The X and Y groups can be in any position on the phenyl rings but typically they are at the 2- or 4-positions on either or both phenyl rings.

Despite what type of X and Y groups are present in the iodonium cation, the sum of the carbon atoms in the X and Y substituents generally is at least 6, and typically at least 8, and up to 40 carbon atoms. Thus, in some compounds, one or more X groups can comprise at least 6 carbon atoms, and Y does not exist (q is 0). Alternatively, one or more Y groups can comprise at least 6 carbon atoms, and X does not exist (p is 0). Moreover, one or more X groups can comprise less than 6 carbon atoms and one or more Y groups can comprise less than 6 carbon atoms as long as the sum of the carbon atoms in both X and Y is at least 6. Still again, there may be a total of at least 6 carbon atoms on both phenyl rings.

In Structure IB, p and q are independently 0 or integers of 1 to 5, provided that either p or q is at least 1. Typically, both p and q are at least 1, or each of p and q is 1. Thus, it is understood that the carbon atoms in the phenyl rings that are not substituted by X or Y groups have a hydrogen atom at those ring positions.

Z^{⊖} is an organic anion represented by the following Structure (IB_{Z}):

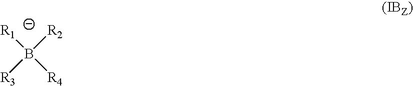

wherein R₁, R₂, R₃, and R₄ are independently substituted or unsubstituted alkyl groups having 1 to 12 carbon atoms (such as methyl, ethyl, n-propyl, iso-propyl, n-butyl, isobutyl, t-butyl, all pentyl isomers, 2-methylpentyl, all hexyl isomers, 2-ethylhexyl, all octyl isomers, 2,4,4-trimethylpentyl, all nonyl isomers, all decyl isomers, all undecyl isomers, all dodecyl isomers, methoxymethyl, and benzyl) other than fluoroalkyl groups, substituted or unsubstituted carbocyclic aryl groups having 6 to 10 carbon atoms in the aromatic ring (such as phenyl, p-methylphenyl, 2,4-methoxyphenyl, naphthyl, and pentafluorophenyl groups), substituted or unsubstituted alkenyl groups having 2 to 12 carbon atoms (such as ethenyl, 2-methylethenyl, allyl, vinylbenzyl, acryloyl, and crotonotyl groups), substituted or unsubstituted alkynyl groups having 2 to 12 carbon atoms (such as ethynyl, 2-methylethynyl, and 2,3-propynyl groups), substituted or unsubstituted cycloalkyl groups having 3 to 8 carbon atoms in the ring structure (such as cyclopropyl, cyclopentyl, cyclohexyl, 4-methylcyclohexyl, and cyclooctyl groups), or substituted or unsubstituted heterocyclyl groups having 5 to 10 carbon, oxygen, sulfur, and nitrogen atoms (including both aromatic and non-aromatic groups, such as substituted or unsubstituted pyridyl, pyrimidyl, furanyl, pyrrolyl, imidazolyl, triazolyl, tetrazoylyl, indolyl, quinolinyl, oxadiazolyl, and benzoxazolyl groups). Alternatively, two or more of R₁, R₂, R₃, and R₄ can be joined together to form a heterocyclic ring with the boron atom, such rings having up to 7 carbon, nitrogen, oxygen, or nitrogen atoms. None of the R₁ through R₄ groups contains halogen atoms and particularly fluorine atoms.

Typically, R₁, R₂, R₃, and R₄ are independently substituted or unsubstituted alkyl or aryl groups as defined above, and more typically, at least 3 of R₁, R₂, R₃, and R₄ are the same or different substituted or unsubstituted aryl groups (such as substituted or unsubstituted phenyl groups). For example, all of R₁, R₂, R₃, and R₄ can be the same or different substituted or unsubstituted aryl groups, or all of the groups are the same substituted or unsubstituted phenyl group. Z^{⊖} can be a tetraphenyl borate wherein the phenyl groups are substituted or unsubstituted (for example, all are unsubstituted).

Representative iodonium borate compounds include but are not limited to, 4-octyloxyphenyl phenyliodonium tetraphenylborate, [4-[(2-hydroxytetradecyl)-oxy]phenyl]phenyliodonium tetraphenylborate, bis(4-t-butylphenyl)iodonium tetraphenylborate, 4-methylphenyl-4′-hexylphenyliodonium tetraphenylborate, 4-methylphenyl-4′-cyclohexylphenyliodonium tetraphenylborate, bis(t-butylphenyl)iodonium tetrakis(pentafluorophenyl)borate, 4-hexylphenyl-phenyliodonium tetraphenylborate, 4-methylphenyl-4′-cyclohexylphenyliodonium n-butyltriphenylborate, 4-cyclohexylphenyl-phenyliodonium tetraphenylborate, 2-methyl-4-t-butylphenyl-4′-methylphenyliodonium tetraphenylborate, 4-methylphenyl-4′-pentylphenyliodonium tetrakis[3,5-bis(trifluoromethyl)phenyl]-borate, 4-methoxyphenyl-4′-cyclohexylphenyliodonium tetrakis(penta-fluorophenyl)borate, 4-methylphenyl-4′-dodecylphenyliodonium tetrakis(4-fluorophenyl)borate, bis(dodecylphenyl)iodonium tetrakis(pentafluorophenyl)-borate, and bis(4-t-butylphenyl)iodonium tetrakis(1-imidazolyl)borate. Mixtures of two or more of these compounds can also be used in the iodonium borate initiator composition.

The diaryliodonium borate compounds can be prepared, in general, by reacting an aryl iodide with a substituted or unsubstituted arene, followed by an ion exchange with a borate anion. Details of various preparatory methods are described in U.S. Pat. No. 6,306,555 (Schulz et al.), and references cited therein, and by Crivello, J. Polymer Sci., Part A: Polymer Chemistry, 37, 4241-4254 (1999).

Co-initiators can also be used, such as metallocenes (including titanocenes and ferrocenes), polycarboxylic acids (for example as described in EP 1,079,972 by Hauck et al.), haloalkyl triazines, thiols, or mercaptans (such as mercaptotriazoles), borate salts, and photooxidants containing a heterocyclic nitrogen that is substituted by an alkoxy or acyloxy group, as described in U.S. Pat. No. 5,942,372 (West et al.).

Metallocenes are organometallic compounds that have one or more cyclopentadienyl ligands that are optionally substituted at one or all of the ring carbons. Each carbon in the five-member ligand ring is coordinated to the transition metal center. Metallocenes are known for having a wide variety of transition metals including iron, titanium, tungsten, molybdenum, nickel, cobalt, chromium, zirconium, and manganese.

For example, ferrocenes have an iron center coordinated by at least one cyclopentadienyl ligand, but ferrocenes also include bicyclopentadienyl “sandwich” compounds. Suitable ferrocene compounds include those that have a hexhapto benzene ligand coordinated to the iron center. Examples of such compounds are described in Col. 7 of U.S. Pat. No. 6,936,384 (Munnelly et al.). Other suitable ferrocenes include compounds having halogenated, aryl-substituted, or haloaryl-substituted cyclopentadienyl ligands.

Titanocenes are also useful in the practice of this invention. Such compounds have a titanium center coordinated by at least one pentahapto cyclopentadienyl ligand and generally include additional ligands that may be known for organometallic complexes. Some suitable titanocene compounds include in their structures aryl ligands, haloaryl ligands, or pyrrole-substituted aryl ligands. Examples of useful titanocenes include those described in Col. 8 of U.S. Pat. No. 6,936,384 (noted above). One commercially available titanocene is (bis)cyclopentadienyl-(bis)2,6-difluoro-3-(pyrr-1-yl)phen-1-yl titanium sold by Ciba Specialty Chemicals as Irgacure® 784, as noted below with the Examples. Other suitable titanocenes are described in U.S. Pat. No. 4,548,891 (Riediker et al.), U.S. Pat. No. 4,590,287 (Riediker et al.), U.S. Pat. No. 5,008,302 (Husler et al.), U.S. Pat. No. 5,106,722 (Husler et al.), U.S. Pat. No. 6,010,824 (Komano et al.), and U.S. Pat. No. 6,153,660 (Fujimaki et al.).

It would be recognized by one skilled in the art that not every initiator (or co-initiator) can be used to advantage with every radiation absorbing compound (or sensitizer) described below. For example, some combinations of initiators and sensitizers may be unsuitable for photospeed or other properties, but it would require only routine experimentation in view of the teaching provided herein for a skilled worker to find the optimal combinations of initiators, optional co-initiators, and radiation absorbing compounds for desired properties.

Thus, several initiator/co-initiator combinations can be used in various embodiments, including but not limited to:

a) a triazine as described above in combination with a co-initiator that is an N-aryl, S-aryl, or O-aryl polycarboxylic acids with at least 2 carboxy groups of which at least one is bonded to the nitrogen, oxygen, or sulfur atom of the aryl moiety (such as aniline diacetic acid and derivatives thereof) as described above,

b) a boron-containing counterion that comprises four of the same or different alkyl or aryl groups, or any combination thereof, wherein the boron-containing counterion is a counterion for an infrared radiation absorbing dye, or is a counterion in an onium salt,

c) a triazine as described above in combination with a co-initiator that is a mercaptan derivative as described above,

d) an onium salt (such as an iodonium salt) as described above in combination with a co-initiator that is a metallocene (for example a titanocene or ferrocene) as described for example in U.S. Pat. No. 6,936,384 (noted above) and EP 684,522A1 (Baumann et al.),

e) an iodonium salt (such as an iodonium borate) as described above in combination with a co-initiator that is a mercaptotriazole as described above,

f) a triazine as described above in combination with an alkyl triarylborate or a tetraarylborate,

g) a polyhaloalkyl-substituted compound or an azinium compound with a polycarboxylic acid, for example as described in EP 1,079,972 (noted above), and

h) a hexaarylbiimidazole and a heterocyclic mercapto compound, such as a mercaptotriazole.

The free radical generating initiators in the initiator composition are generally present in the radiation-sensitive composition (or imageable layer) in an amount of at least 0.5% and up to and including 30%, and typically at least 2 and up to and including about 20%, based on total dry weight of the composition (or imageable layer).

The radiation-sensitive composition (and imageable layer) generally includes one or more infrared radiation absorbing compounds (or sensitizers) that absorb imaging radiation (or sensitize the composition to imaging radiation) having a spectral sensitivity in the near-IR and IR regions of the electromagnetic spectrum, that is, at least 700 nm and up to and including 1500 nm and typically of at least 700 nm and up to and including about 1200 nm.

Useful IR-sensitive radiation absorbing compounds include carbon blacks and other IR-absorbing pigments and various IR-sensitive dyes (“IR dyes”). Useful pigment include Heliogen Green, Nigrosine Base, iron (III) oxides, manganese oxide, Prussian Blue, Paris Blue, and carbon blacks such as carbon blacks that are surface-functionalized with solubilizing groups are well known in the art. Carbon blacks that are grafted to hydrophilic, nonionic polymers, such as FX-GE-003 (manufactured by Nippon Shokubai), or which are surface-functionalized with anionic groups, such as CAB-O-JET® 200 or CAB-O-JET® 300 (manufactured by the Cabot Corporation) are also useful.

Examples of suitable IR dyes include but are not limited to, azo dyes, squarilium dyes, croconate dyes, triarylamine dyes, thioazolium dyes, indolium dyes, oxonol dyes, oxazolium dyes, cyanine dyes, merocyanine dyes, phthalocyanine dyes, indocyanine dyes, indotricarbocyanine dyes, oxatricarbocyanine dyes, thiocyanine dyes, thiatricarbocyanine dyes, merocyanine dyes, cryptocyanine dyes, naphthalocyanine dyes, polyaniline dyes, polypyrrole dyes, polythiophene dyes, chalcogenopyryloarylidene and bi(chalcogenopyrylo) polymethine dyes, oxyindolizine dyes, pyrylium dyes, pyrazoline azo dyes, oxazine dyes, naphthoquinone dyes, anthraquinone dyes, quinoneimine dyes, methine dyes, arylmethine dyes, squarine dyes, oxazole dyes, croconine dyes, porphyrin dyes, and any substituted or ionic form of the preceding dye classes. Suitable dyes are also described in U.S. Pat. No. 5,208,135 (Patel et al.), U.S. Pat. No. 6,153,356 (Urano et al.), U.S. Pat. No. 6,264,920 (Achilefu et al.), U.S. Pat. No. 6,309,792 (Hauck et al.), and U.S. Pat. No 6,787,281 (Tao et al.), and EP 1,182,033A2 (noted above).

A general description of one class of suitable cyanine dyes is shown by the formula in paragraph [0026] of WO 2004/101280 (Munnelly et al.), incorporated herein by reference, and useful IR absorbing compounds are identified below with the Examples.

In addition to low molecular weight IR-absorbing dyes, IR dye chromophores bonded to polymers can be used as well. Moreover, IR dye cations can be used as well, that is, the cation is the IR absorbing portion of the dye salt that ionically interacts with a polymer comprising carboxy, sulfo, phospho, or phosphono groups in the side chains.

Near infrared absorbing cyanine dyes are also useful and are described for example in U.S. Pat. No. 6,309,792 (Hauck et al.), U.S. Pat. No. 6,264,920 (Achilefu et al.), U.S. Pat. No. 6,153,356 (Urano et al.), U.S. Pat. No. 5,496,903 (Watanate et al.). Suitable dyes may be formed using conventional methods and starting materials or obtained from various commercial sources including American Dye Source (Baie D'Urfe, Quebec, Canada) and FEW Chemicals (Germany). Other useful dyes for near infrared diode laser beams are described, for example, in U.S. Pat. No. 4,973,572 (DeBoer).

Other useful IR-sensitive dyes having the desired chromophore can be defined by the following Structure DYE-I:

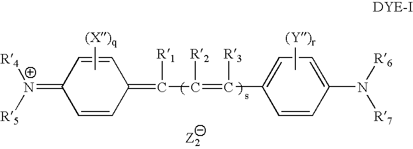

wherein R₁′, R₂′, and R₃′ each independently represents hydrogen, or a halo, cyano, substituted or unsubstituted alkoxy (having 1 to 8 carbon atoms, both linear and branched alkoxy groups), substituted or unsubstituted aryloxy (having 6 to 10 carbon atoms in the carbocyclic ring), substituted or unsubstituted acyloxy (having 2 to 6 carbon atoms), carbamoyl, substituted or unsubstituted acyl, substituted or unsubstituted acylamido, substituted or unsubstituted alkylamino (having at least one carbon atom), substituted or unsubstituted carbocyclic aryl groups (having 6 to 10 carbon atoms in the aromatic ring, such as phenyl and naphthyl groups), substituted or unsubstituted alkyl groups (having 1 to 8 carbon atoms, both linear and branched isomers), substituted or unsubstituted arylamino, or substituted or unsubstituted heteroaryl (having at least 5 carbon and heteroatoms in the ring) group. Alternatively, any two of R₁′, R₂′, and R₃′ groups may be joined together or with an adjacent aromatic ring to complete a 5- to 7-membered substituted or unsubstituted carbocyclic or heterocyclic ring.

For example, R₁′, R₂′, and R₃′ are independently hydrogen, a substituted or unsubstituted carbocyclic aryl group, and a substituted or unsubstituted heteroaryl group.

R₄′, R₅′, R₆′, and R₇′ each independently represents hydrogen, a substituted or unsubstituted alkyl group (having 1 to 10 carbon atoms), a substituted or unsubstituted cycloalkyl group (having from 4 to 6 carbon atoms in the ring), a substituted or unsubstituted aryl group (having at least 6 carbon atoms in the ring), or a substituted or unsubstituted heteroaryl group (having 5 to 10 carbon and heteroatoms in the ring).

Alternatively, R₄′ and R₅′ or R₆′ and R₇′ can be joined together to form a substituted or unsubstituted 5- to 9-membered heterocyclic ring, or R₄′, R₅′, R₆′, or R₇′ can be joined to the carbon atom of the adjacent aromatic ring at a position ortho to the position of attachment of the anilino nitrogen to form, along with the nitrogen to which they are attached, a substituted or unsubstituted 5- or 6-membered heterocyclic ring.

For example, R₄′, R₅′, R₆′, and R₇′ are independently a substituted or unsubstituted alkyl group, a substituted or unsubstituted cycloalkyl group, a substituted or unsubstituted aryl group, or R₄′ and R₅′ or R₆′ and R₇′ can be joined together to form a substituted or unsubstituted 5- to 7-membered heterocyclic ring. Also, they can be independently substituted or unsubstituted alkyl groups of 1 to 8 carbon atoms, substituted or unsubstituted phenyl groups, or R₄′ and R₅′ or R₆′ and R₇′ can be joined together to form a substituted or unsubstituted 5- to 7-membered heteroaryl group.

In the DYE I structure, s is 1, 2, or 3, Z₂ is a monovalent anion, X″ and Y″ are each independently R₁′ or the atoms necessary to complete a substituted or unsubstituted 5- to 7-membered fused carbocyclic or heterocyclic ring, and q and r are independently integers from 1 to 4.

For example, X″ and Y″ are independently hydrogen or the carbon and heteroatoms needed to provide a fused aryl or heteroaryl ring.

Further details of such bis(aminoaryl)pentadiene IR dyes are provided, including representative IR dyes identified as DYE 1 through DYE 17, DYE 19, and DYE 20, in U.S. Pat. No. 6,623,908 (Zheng et al.).

Some useful infrared radiation absorbing dyes have a tetraaryl pentadiene chromophore. Such chromophore generally includes a pentadiene linking group having 5 carbon atoms in the chain, to which are attached two substituted or unsubstituted aryl groups at each end of the linking group. The pentadiene linking group can also be substituted with one or more substituents in place of the hydrogen atoms, or two or more hydrogen atoms can be replaced with atoms to form a ring in the linking group as long as there are alternative carbon-carbon single bonds and carbon-carbon double bonds in the chain.

Such IR-sensitive dyes can be represented by the following Structure DYE-II:

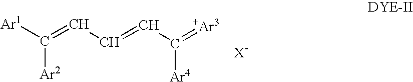

wherein Ar¹ through Ar⁴ are the same or different substituted or unsubstituted aryl groups having at least carbon atoms in the aromatic ring (such as phenyl, naphthyl, and anthryl, or other aromatic fused ring systems) wherein 1 to 3 of the aryl groups are substituted with the same or different tertiary amino group (such as in the 4-position of a phenyl group). Typically two of the aryl groups are substituted with the same or different tertiary amino group, and usually at different ends of the polymethine chain (that is, molecule). For example, Ar¹ or Ar² and Ar³ or Ar⁴ bear the tertiary amine groups. Representative amino groups include but are not limited to those substituted with substituted or unsubstituted alkyl groups having up to 10 carbon atoms or aryl groups such as dialkylamino groups (such as dimethylamino and diethylamino), diarylamino groups (such as diphenylamino), alkylarylamino groups (such as N-methylanilino), and heterocyclic groups such as pyrrolidino, morpholino, and piperidino groups. The tertiary amino group can form part of a fused ring such that one or more of Ar¹ through Ar⁴ can represent a julolidine group.

Besides the noted tertiary groups noted above, the aryl groups can be substituted with one or more substituted or unsubstituted alkyl groups having 1 to 10 carbon atoms, halo atoms (such as chloro or bromo), hydroxyl groups, thioether groups, and substituted or unsubstituted alkoxy groups having 1 to 10 carbon atoms. Substituents that contribute electron density to the conjugated system are useful. While they are not specifically shown in Structure (DYE-II), substituents or fused rings may also exist on (or as part of) the conjugated chain connecting the aryl groups.

In Structure (DYE-II), X⁻ is a suitable counterion that may be derived from a strong acid, and include such anions as ClO₄⁻, BF₄⁻, CF₃SO₃⁻, PF₆⁻, AsF₆⁻, SbF₆⁻, and perfluoroethylcyclohexylsulfonate. Other cations include boron-containing anions as described above (borates), methylbenzenesulfonic acid, benzenesulfonic acid, methanesulfonic acid, p-hydroxybenzenesulfonic acid, p-chlorobenzenesulfonic acid, and halides.

Some embodiments include a borate anion for X-, such as a tetra-substituted borate anion, which substituents can be the same or different alkyl (having 1 to 20 carbon atoms) or aryl groups (phenyl or naphthyl groups), which groups can be further substituted if desired. Particularly useful boron-containing counterions of this type include alkyltriarylborates, dialkyldiarylborates, and tetraarylborates. Examples of these boron-containing counterions are described for example, in EP 438,123A2 (Murofushi et al.).

The radiation absorbing compound (or sensitizer) can be present in the radiation-sensitive composition (and imageable layer) in an amount generally of at least 1% and up to and including 30% and typically at least 3 and up to and including 20%, based on total solids. The particular amount needed for this purpose would be readily apparent to one skilled in the art, depending upon the specific compound used to provide the desired chromophore.

Other polymeric binders include but are not limited to those having one or more ethylenically unsaturated pendant groups (reactive vinyl groups) attached to the polymer backbone. Such reactive groups are capable of undergoing polymerizable or crosslinking in the presence of free radicals. The pendant groups can be directly attached to the polymer backbone with a carbon-carbon direct bond, or through a linking group (“X”) that is not particularly limited. The reactive vinyl groups may be substituted with at least one halogen atom, carboxy group, nitro group, cyano group, amide group, or alkyl, aryl, alkoxy, or aryloxy group, and particularly one or more alkyl groups. In some embodiments, the reactive vinyl group is attached to the polymer backbone through a phenylene group as described, for example, in U.S. Pat. No. 6,569,603 (Furukawa et al.). Other useful polymeric binders have vinyl groups in pendant groups that are described, for example in EP 1,182,033A1 (Fujimaki et al.) and U.S. Pat. No. 4,874,686 (Urabe et al.) and U.S. Pat. No. 7,041,416 (Wakata et al.) that are incorporated by reference, especially with respect to the general formulae (1) through (3) noted in EP 1,1 82,033A1. Some useful pendant reactive vinyl groups are alkenyl groups including but not limited to allyl esters, styryl, and (meth)acryloyl groups. For example, such groups can be provided by allyl (meth) acrylates, or by reacting a polymer precursor with an allyl halide, 4-vinylbenzyl chloride, or (meth)acryloyl chloride using conditions that would be apparent to a skilled worker in the art.

Additional polymeric binders may be any of those known in the art for use in negative-working radiation-sensitive compositions other than those mentioned above. The secondary polymeric binder(s) may be present in an amount of from about 10 to 100 weight % and typically from about 20 to about 95%, based on the dry coated weight of the radiation-sensitive composition (or imageable layer).

The polymeric binders may be homogenous, that is, dissolved in the coating solvent, or they may exist as discrete particles. Such polymeric binders include but are not limited to, (meth)acrylic acid and acid ester resins [such as (meth)acrylates], polyvinyl acetals, phenolic resins, polymers derived from styrene, N-substituted cyclic imides or maleic anhydrides, such as those described in EP 1,182,033 (Fujimaki et al.) and U.S. Pat. No. 6,309,792 (Hauck et al.), U.S. Pat. No. 6,352,812 (Shimazu et al.), U.S. Pat. No. 6,569,603 (Furukawa et al.), and U.S. Pat. No. 6,893,797 (Munnelly et al.). Also useful are the vinyl carbazole polymers described in copending and commonly assigned U.S. Pat. No. 7,175,949 (Tao et al.). Copolymers of polyethylene glycol methacrylate/acrylonitrile/styrene in particulate form, dissolved copolymers derived from carboxyphenyl methacrylamide/acrylonitrile/methacrylamide/N-phenyl maleimide, copolymers derived from polyethylene glycol methacrylate/acrylonitrile/vinylcarbazole/-styrene/methylacrylic acid, copolymers derived from N-phenyl maleimide/methacrylamide/methacrylic acid, copolymers derived from urethane-acrylic intermediate A (the reaction product of p-toluene sulfonyl isocyanate and hydroxyl ethyl methacrylate)/acrylonitrile/N-phenyl maleimide, and copolymers derived from N-methoxymethyl methacrylamide/methacrylic acid/acrylonitrile/n-phenylmaleimide are useful.

Other useful polymeric binders are particulate poly(urethane-acrylic) hybrids that are distributed (usually uniformly) throughout the imageable layer. Each of these hybrids has a molecular weight of from about 50,000 to about 500,000 and the particles have an average particle size of from about 10 to about 10,000 nm (typically from about 30 to about 500 nm.

Some poly(urethane-acrylic) hybrids are commercially available in dispersions from Air Products and Chemicals, Inc. (Allentown, Pa.), for example, as the Hybridur® 540, 560, 570, 580, 870, 878, 880 polymer dispersions. These dispersions generally include at least 30% solids of the poly(urethane-acrylic) hybrid particles in a suitable aqueous medium that may also include commercial surfactants, anti-foaming agents, dispersing agents, anti-corrosive agents, and optionally pigments and water-miscible organic solvents. Blends of particles of two or more poly(urethane-acrylic) hybrids, such as a blend of Hybridur® 570 polymer dispersion with Hybridur® 870 polymer dispersion, could be used.

The radiation-sensitive composition and imageable layer can further comprise one or more phosphate (meth)acrylates, each of which has a molecular weight generally greater than 200 and typically at least 300 and up to and including 1000. By “phosphate (meth)acrylate” we also mean to include “phosphate methacrylates” and other derivatives having substituents on the vinyl group in the acrylate moiety.

Each phosphate moiety is typically connected to an acrylate moiety by an aliphatic chain [that is, an -(aliphatic-O)-chain] such as an alkyleneoxy chain [that is an -(alkylene-O)ₘ-chain] composed of at least one alkyleneoxy unit, in which the alkylene moiety has 2 to 6 carbon atoms and can be either linear or branched and m is 1 to 10. For example, the alkyleneoxy chain can comprise ethyleneoxy units, and m is from 2 to 8 or m is from 3 to 6. The alkyleneoxy chains in a specific compound can be the same or different in length and have the same or different alkylene group.

Useful phosphate (meth)acrylates can be represented by the following Structure (III):

P(═O)(OM)ₙ(OR)₃₋ₙ (III)

wherein n is 1 or 2, M is hydrogen or a monovalent cation (such as an alkali metal ion, ammonium cations including cations that include one to four hydrogen atoms). For example, useful M cations include but are not limited to sodium, potassium, —NH₄, —NH(CH₂CH₂OH)₃, and —NH₃(CH₂CH₂OH). When n is 2, the M groups are the same or different. The compounds wherein M is hydrogen are particularly useful.

The R groups are independently the same or different groups represented by the following Structure (IV):

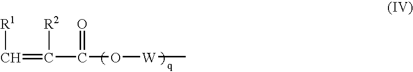

wherein R¹ and R² are independently hydrogen, or a halo (such as chloro or bromo) or substituted or unsubstituted alkyl group having 1 to 6 carbon atoms (such as methyl, chloromethyl, methoxymethyl, ethyl, isopropyl, and t-butyl groups). In many embodiments, one or both of R¹ and R² are hydrogen or methyl, and in some embodiments, R¹ is hydrogen and R² is methyl).

W is an aliphatic group having at least 2 carbon or oxygen atoms, or combination of carbon and oxygen atoms, in the chain, and q is 1 to 10. Thus, W can include one or more alkylene groups having 1 to 8 carbon atoms that are interrupted with one or more oxygen atoms (oxy groups), carbonyl, oxycarbonyl, or carbonyl oxy groups. For example, one such aliphatic group is an alkylenecarbonyloxyalkylene group. Useful alkylene groups included in the aliphatic groups have 2 to 5 carbon atoms and can be branched or linear in form.

The R groups can also independently be the same or different groups represented by the following Structure (V):

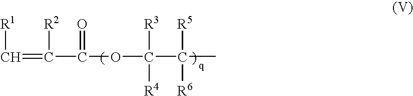

wherein R¹, R², and q are as defined above and R³ through R⁶ are independently hydrogen or a substituted or unsubstituted alkyl group having 1 to 6 carbon atoms (such as methyl, methoxymethyl), ethyl, chloromethyl, hydroxymethyl, ethyl, iso-propyl, n-butyl, t-butyl, and n-pentyl groups). Typically, R³ through R⁶ are independently hydrogen or methyl, and in most embodiments, all are hydrogen.

In Structures IV and V, q is 1 to 10, or from 2 to 8, for example from 3 to 6.

Representative phosphate (meth)acrylates are described for example, in U.S. Pat. No. 7,175,969 (Ray et al.).

The phosphate acrylate can be present in an amount of at least 0.5 and up to and including 20% and typically at least 0.9 and up to and including 10%, by weight of the total solids.

The radiation-sensitive composition (and imageable layer) can also include a “primary additive” that is a poly(alkylene glycol) or an ether or ester thereof that has a molecular weight of at least 200 and up to and including 4000. This primary additive is present in an amount of at least 2 and up to and including 50 weight %, based on the total dry weight. Useful primary additives include, but are not limited to, one or more of polyethylene glycol, polypropylene glycol, polyethylene glycol methyl ether, polyethylene glycol dimethyl ether, polyethylene glycol monoethyl ether, polyethylene glycol diacrylate, ethoxylated bisphenol A di(meth)acrylate, and polyethylene glycol mono methacrylate. Also useful are SR9036 (ethoxylated (30) bisphenol A dimethacrylate), CD9038 (ethoxylated (30) bisphenol A diacrylate), and SR₄₉₄ (ethoxylated (5) pentaerythritol tetraacrylate), and similar compounds all of which can be obtained from Sartomer Company, Inc. In some embodiments, the primary additive may be “non-reactive” meaning that it does not contain polymerizable vinyl groups.

The radiation-sensitive composition (and imageable layer) can also include a “secondary additive” that is a poly(vinyl alcohol), a poly(vinyl pyrrolidone), poly(vinyl imidazole), or polyester in an amount of up to and including 20 weight % based on the total dry weight.

The radiation-sensitive composition (and imageable layer) can also include a variety of optional compounds including but not limited to, dispersing agents, humectants, biocides, plasticizers, surfactants for coatability or other properties, viscosity builders, dyes or colorants to allow visualization of the written image (such as crystal violet, methyl violet, ethyl violet, Victoria blue, malachite green, brilliant green, and phthalocyanine pigments such as copper phthalocyanine and metal-free phthalocyanine), pH adjusters, drying agents, defoamers, preservatives, antioxidants, development aids, rheology modifiers or combinations thereof, or any other addenda commonly used in the lithographic art, in conventional amounts. Useful viscosity builders include hydroxypropyl cellulose, hydroxyethyl cellulose, carboxymethyl cellulose, and poly(vinyl pyrrolidones).

In some embodiments, the imageable element may include what is conventionally known as an overcoat (also known as an “oxygen impermeable topcoat” or “oxygen barrier layer”) disposed over the imageable layer, for example, as described in EP Patent Publications 1,788,429, 1,788,431 and 1,788,434 (all noted above) and U.S. Patent Application Publication 2005/0266349 (noted above). Such overcoat layers comprise a poly(vinyl alcohol) as the predominant polymeric binder. If present, the overcoat is the outermost layer of the imageable element.

The negative-working lithographic printing plate precursors can be formed by suitable application of a radiation-sensitive composition as described above to a suitable substrate (described above) to form an imageable layer. Typically, there is only a single imageable layer comprising the radiation-sensitive composition that is directly applied to the substrate without any intermediate layer.

A radiation-sensitive composition containing the components described above can be applied to the substrate as a solution or dispersion in a coating liquid using any suitable equipment and procedure, such as spin coating, knife coating, gravure coating, die coating, slot coating, bar coating, wire rod coating, roller coating, or extrusion hopper coating. The composition can also be applied by spraying onto a suitable support (such as an on-press printing cylinder).

Illustrative of such manufacturing methods is mixing the free radically polymerizable component, polymeric binder(s), initiator composition, radiation absorbing compound, and any other components of the radiation-sensitive composition in a suitable coating solvent including water, organic solvents [such as glycol ethers including 1-methoxypropan-2-ol, methyl ethyl ketone (2-butanone), methanol, ethanol, 1-methoxy-2-propanol, iso-propyl alcohol, acetone, γ-butyrolactone, n-propanol, tetrahydrofuran, and others readily known in the art, as well as mixtures thereof], or mixtures thereof, applying the resulting solution to a substrate, and removing the solvent(s) by evaporation under suitable drying conditions. Some representative coating solvents and negative-working imageable layer formulations are described in the Invention Examples 4-6 below. After proper drying, the coating weight of the imageable layer is generally at least 0. 1 and up to and including 5 g/m² or at least 0.5 and up to and including 3.5 g/m².

Once the imageable layer formulation has been applied and dried on the substrate, and any overcoat formulation has been applied and dried, the negative-working lithographic printing plate precursor can be enclosed in water-impermeable material that substantially inhibits the transfer of moisture to and from the negative-working lithographic printing plate precursor.

By “enclosed”, we mean that the negative-working lithographic printing plate precursor is wrapped, encased, enveloped, or contained in a manner such that both upper and lower surfaces and all edges are within the water-impermeable sheet material. Further details of this process are provided in U.S. Pat. No. 7,175,969 (noted above).

### Single-Layer Positive-Working Lithographic Printing Plate Precursors

In general, single-layer positive-working imageable elements are formed by suitable application of an imageable layer formulation containing one or more polymeric binders to a suitable substrate (described above) to form an imageable layer.

The single-layer, positive-working imageable element also includes one or more radiation absorbing compounds. These compounds are usually sensitive to near-infrared or infrared radiation and thus, the radiation absorbing compounds having spectral sensitivity to from about 700 to about 1500 nm and typically from about 700 to about 1200 nm. Examples of suitable infrared radiation-sensitive compounds, including IR dyes are described above in relation to the negative-working imageable elements.

The radiation absorbing compound is generally present in the imageable element in an amount sufficient to render the imageable layer soluble to an aqueous developer after exposure to appropriate radiation. This amount is generally at least 0.5% and up to 30 weight % and typically from about 3 to about 10 weight % (based on total dry layer weight). In most embodiments, the radiation absorbing compound is present in the single imageable layer. Alternatively or additionally, radiation absorbing compounds may be located in a separate layer that is in thermal contact with the single imageable layer.

In addition, solubility-suppressing components are optionally incorporated into the single imageable layer. Such components act as dissolution inhibitors that function as solubility-suppressing components for the polymeric binders before imagewise exposure. Dissolution inhibitors typically have polar functional groups that are believed to act as acceptor sites for hydrogen bonding with various groups in the polymeric binders. The acceptor sites comprise atoms with high electron density, and can be selected from electronegative first row elements such as carbon, nitrogen, and oxygen. Useful polar groups for dissolution inhibitors include but are not limited to, ether groups, amine groups, azo groups, nitro groups, ferrocenium groups, sulfoxide groups, sulfone groups, diazo groups, diazonium groups, keto groups, sulfonic acid ester groups, phosphate ester groups, triarylmethane groups, onium groups (such as sulfonium, iodonium, and phosphonium groups), groups in which a nitrogen atom is incorporated into a heterocyclic ring, and groups that contain a positively charged atom (such as quaternized ammonium group). Compounds that contain a positively-charged nitrogen atom useful as dissolution inhibitors include, for example, tetraalkyl ammonium compounds and quaternized heterocyclic compounds such as quinolinium compounds, benzothiazolium compounds, pyridinium compounds, and imidazolium compounds. Further details and representative compounds useful as dissolution inhibitors are described for example in U.S. Pat. No. 6,294,311 (noted above). Useful dissolution inhibitors include triarylmethane dyes such as ethyl violet, crystal violet, malachite green, brilliant green, Victoria blue B, Victoria blue R, and Victoria pure blue BO, BASONYL® Violet 610 and D11 (PCAS, Longjumeau, France).

The polymeric binders used in the imageable layer are generally soluble in alkaline developers (defined below) after thermal imaging. In some embodiments of the positive-working imageable elements, the polymeric binders are present in an amount of at least 10 weight % and typically from about 20 to 100 weight % of the total dry imageable layer weight.

The polymeric binders can be poly(vinyl phenols) or derivatives thereof, or phenolic polymers. They may include carboxylic (carboxy), sulfonic (sulfo), phosphonic (phosphono), or phosphoric acid groups that are incorporated into the polymer molecule. Other useful additional polymers include but are not limited to, novolak resins, resole resins, poly(vinyl acetals) having pendant phenolic groups, and mixtures of any of these resins (such as mixtures of one or more novolak resins and one or more resole resins). Generally, such resins have a number average molecular weight of at least 3,000 and up to 200,000, and typically from about 6,000 to about 100,000, as determined using conventional procedures. Typical novolak resins include but are not limited to, phenol-formaldehyde resins, cresol-formaldehyde resins, phenol-cresol-formaldehyde resins, p-t-butylphenol-formaldehyde resins, and pyrogallol-acetone resins, such as novolak resins prepared from reacting m-cresol or a m,p-cresol mixture with formaldehyde using conventional conditions. For example, some useful novolak resins include xylenol-cresol resins, for example, SPN400, SPN420, SPN460, and VPN1100 (that are available from AZ Electronics) and EP25D40G and EP25D50G.

Other useful polymeric binders include polyvinyl compounds having phenolic hydroxyl groups, include poly(hydroxystyrenes) and copolymers containing recurring units of a hydroxystyrene and polymers and copolymers containing recurring units of substituted hydroxystyrenes. Also useful are branched poly(hydroxystyrenes) having multiple branched hydroxystyrene recurring units derived from 4-hydroxystyrene as described for example in U.S. Pat. No. 5,554,719 (Sounik) and U.S. Pat. No. 6,551,738 (Ohsawa et al.), and U.S. Published Patent Applications 2003/0050191 (Bhatt et al.) and 2005/0051053 (Wisnudel et al.), and in copending and commonly assigned U.S. patent application Ser. No. 11/474,020 (filed Jun. 23, 2006 by Levanon et al.), that is incorporated herein by reference. The branched poly(hydroxystyrenes) can be homopolymers or copolymers with non-branched hydroxystyrene recurring units.

One group of useful polymeric binders are poly(vinyl phenol) and derivatives thereof. Such polymers are obtained generally by polymerization of vinyl phenol monomers, that is, substituted or unsubstituted vinyl phenols. Substituted vinyl phenol recurring units include those described below for the “a” recurring units in Structure (I). Some vinyl phenol copolymers are described in EP 1,669,803A (Barclay et al.).

Other useful polymeric binders are modified novolak or resole resins that are represented by Structure (POLYMER):

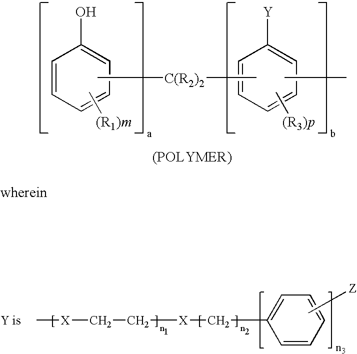

a is from about 90 to about 99 mol % (typically from about 92 to about 98 mol %), b is from about 1 to about 10 mol % (typically from about 2 to about 8 mol %), R₁ and R₃ are independently hydrogen or hydroxy, alkyl, or alkoxy groups, R₂ is hydrogen or an alkyl group, X is an alkylene, oxy, thio, —OC(═O)Ar—, —OC(═O)CH═CH—, or —OCO(CH₂)ₙ₄-group wherein Ar is an aryl group, m and p are independently 1 or 2, n₃ is 0 or an integer up to 5 (for example 0, 1, 2, or 3), n₂ is 0 or an integer up to 5 (for example, 0, 1, or 2), n₃ is 0 or 1 (typically 0), n₄ is at least 1 (for example, up to 8), and Z is —C(═O)OH, —S(═O)₂OH, —P(═O)(OH)₂, or —OP(═O)(OH)₂.

In some embodiments, the polymeric binder comprises recurring units represented by Structure (POLYMER) wherein a is from about 92 to about 98 mol %, b is from about 2 to about 8 mol % and Z is —C(═O)OH, and is present at a dry coverage of from about 15 to 100 weight % based on the total dry weight of the layer.

Other polymeric binders that may be in the imageable layer include modified phenolic resins such as modified novolak and resole resins, and such resins can also include one or more pendant diazo, carboxylate ester, phosphate ester, sulfonate ester, sulfinate ester, or ether groups. The hydroxy groups of the phenolic resins can be converted to -T-Z groups in which T represents a polar group and Z represents a non-diazide functional group as described for example in U.S. Pat. No. 6,218,083 (McCullough et al.) and WO 99/001795 (McCullough et al.). The hydroxy groups can also be derivatized with diazo groups containing o-naphthoquinone diazide moieties as described for example in U.S. Pat. No. 5,705,308 (West et al.) and U.S. Pat. No. 5,705,322 (West et al.). Other useful polymeric binders include acrylate copolymers as described for example in EP 737,896A (Ishizuka et al.), cellulose esters and poly(vinyl acetals) as described for example in U.S. Pat. No. 6,391,524 (Yates et al.), DE 10 239 505 (Timpe et al.), and WO 2004081662 (Memetea et al.).

Still other useful polymeric binders are poly(vinyl acetals) as described for example in U.S. Pat. No. 6,255,033 (Levanon et al.) and U.S. Pat. No. 6,541,181 (Levanon et al.). Still other useful poly(vinyl acetals) are described in copending and commonly assigned U.S. Ser. No. 11/677,599 (filed Feb. 22, 2007 by Levanon, Postel, Rubin, and Kurtser), Ser. No. 11/769,766 (filed Jun. 28, 2007 by Levanon, Lurie, and Kampel), and Ser. No. 11/959,492 (filed Dec. 18, 2007 by Nakash and Levanon), each of which applications is incorporated herein by reference in relation to these polymeric binders.

The single imageable layer can further include a variety of additives including dispersing agents, humectants, biocides, plasticizers, surfactants for coatability or other properties, viscosity builders, dyes or colorants to allow visualization of the written image, pH adjusters, drying agents, defoamers, preservatives, antioxidants, development aids, rheology modifiers, or combinations thereof, or any other addenda commonly used in the lithographic art, in conventional amounts.

The single-layer imageable element can be prepared by applying the layer formulation over the surface of the substrate (and any other hydrophilic layers provided thereon) using conventional coating or lamination methods. Thus, the formulations can be applied by dispersing or dissolving the desired ingredients in a suitable coating solvent, and the resulting formulations are sequentially or simultaneously applied to the substrate using suitable equipment and procedures, such as spin coating, knife coating, gravure coating, die coating, slot coating, bar coating, wire rod coating, roller coating, or extrusion hopper coating. The formulations can also be applied by spraying onto a suitable support (such as an on-press printing cylinder or printing sleeve).

The coating weight for the single imageable layer can be from about 0.5 to about 2.5 g/m² and typically from about 1 to about 2 g/m².

The selection of solvents used to coat the imageable layer formulation depends upon the nature of the polymeric materials and other components in the formulations. Generally, the imageable layer formulation is coated out of acetone, methyl ethyl ketone, or another ketone, tetrahydrofuran, 1-methoxypropan-2-ol, 1-methoxy-2-propyl acetate, and mixtures thereof using conditions and techniques well known in the art.

Alternatively, the layer(s) may be applied by conventional extrusion coating methods from melt mixtures of the respective layer compositions. Typically, such melt mixtures contain no volatile organic solvents.

Intermediate drying steps may be used between applications of the various layer formulations to remove solvent(s) before coating other formulations. Drying steps may also help in preventing the mixing of the various layers.

After coating and drying the various layers, the lithographic printing plate precursors can be further “conditioned” with a heat treatment at from about 40 to about 90° C. for at least 4 hours (for example, at least 20 hours) under conditions that inhibit the removal of moisture from the dried layers. For example, the heat treatment is carried out at from about 50 to about 70° C. for at least 24 hours. During the heat treatment, the lithographic printing plate precursor is wrapped or encased in a water-impermeable sheet material to represent an effective barrier to moisture removal from the precursor, or the heat treatment of the precursor is carried out in an environment in which relative humidity is controlled to at least 25%. In addition, the water-impermeable sheet material can be sealed around the edges of the precursor, with the water-impermeable sheet material being a polymeric film or metal foil that is sealed around the edges of the precursor. Further details of such conditioning are provided for example, in U.S. Pat. No. 7,175,969 (Ray et al.).

In some embodiments, this heat treatment can be carried out with a stack comprising at least 100 of the same lithographic printing plate precursors, or when the precursor is in the form of a coil or web. While being conditioned in a stack, the individual precursors may be separated by suitable interleaving papers. Such papers are available from several commercial sources. The interleaving papers may be kept between the precursors after conditioning during packing and shipping and until they are used by the customer.

### Multi-Layer Positive-Working Lithographic Printing Plate Precursors

These lithographic printing plate precursors generally have at least two imageable layers, such as an inner layer (also known in the art as an “underlayer”), and an outer layer (also known in the art as a “top layer” or “topcoat”) disposed over the inner layer. Before thermal (or infrared) imaging, the outer layer is generally insoluble or non-removable by a processing solution (as defined below) within the usual time allotted for development, but after thermal imaging, the exposed regions of the outer layer are soluble in the processing solution. The inner layer is also generally removable by the processing solution. An infrared radiation absorbing compound (described above for the negative-working lithographic printing plate precursors) can also be present, typically only in the inner layer but it may optionally be present only or additionally in a separate layer between the inner and outer layers. However, in other embodiments, the radiation absorbing compound may be in the outer layer only, or in both the outer and inner layers, as described for example in EP 1,439,058A2 (Watanabe et al.) and EP 1,738,901A1 (Lingier et al.), or in an intermediate layer as described.

These lithographic printing plate precursors are formed by suitable application of two or more imageable layer compositions or formulations onto a suitable substrate (described above).

The lithographic printing plate precursor also includes one or more infrared radiation absorbing compounds (“IR absorbing compounds”) that absorb radiation from about 600 to about 1200 nm and typically from about 700 to about 1200 nm with minimal absorption at 300 to 600 nm. Such compounds are described above with the single-layer positive-working lithographic printing plate precursors.

The infrared radiation absorbing compound is generally present in the lithographic printing plate precursor in an amount of at least 0.5% and up to 30 weight % and typically from about 3 to about 25 weight % (based on total dry layer weight). The particular amount needed for this purpose would be readily apparent to one skilled in the art, depending upon the specific compound used and the properties of the alkaline developer to be used. In most embodiments, the IR radiation absorbing compound is present in the inner layer only, but as noted above, optionally it can be in other locations in addition to or alternatively to, the inner layer.

Inner Layer:

In the multi-layer lithographic printing plate precursors, the inner layer is disposed between the outer layer and the substrate. Typically, it is disposed directly on the substrate (including any hydrophilic coatings as described above). The inner layer comprises a first polymeric binder that is removable by the gum and typically soluble in the gum to reduce sludging in the processor. In addition, the first polymeric binder is usually insoluble in the solvent used to coat the outer layer so that the outer layer can be coated over the inner layer without dissolving the inner layer. Mixtures of these first polymeric binders can be used if desired in the inner layer.

Useful first polymeric binders for the inner layer include (meth)acrylonitrile polymers (derived at least in part from a (meth)acrylonitrile), (meth)acrylic resins comprising carboxy groups, polyvinyl acetals, maleated wood rosins, a vinyl acetate-crotonate-vinyl neodecanoate copolymer, a phenolic resin, styrene-maleic anhydride copolymers, (meth)acrylamide polymers (derived at least in part from a (meth)acrylamide) including polymers derived at least in part from an N-alkoxyalkyl methacrylamide, polymers derived at least in part from a (meth)acrylate having pendant hydroxy groups, polymers derived at least in part from an N-substituted cyclic imide, polymers having pendant cyclic urea groups, a polymer derived at least in part from styrene or a styrene derivative, a polymer derived at least in part from a phosphate (meth)acrylate ester, a copolymer derived from an N-substituted cyclic imide, a (meth)acrylonitrile, a (meth)acrylamide, and (meth)acrylic acid. Various combinations of these polymers can also be used.

For example, useful first polymeric binders include (meth)acrylonitrile polymers, and copolymers derived from a combination of at least one N-substituted cyclic imide (especially N-phenylmaleimide), a (meth)acrylamide (especially methacrylamide), a monomer having a pendant cyclic urea group, and a (meth)acrylic acid (especially methacrylic acid). First polymeric binders of this type include copolymers that comprise from about 20 to about 75 mol % and typically about 35 to about 60 mol % or recurring units derived from N-phenylmaleimide, N-cyclohexyl-maleimide, N-(4-carboxyphenyl)maleimide, N-benzylmaleimide, or a mixture thereof, from about 10 to about 50 mol % and typically from about 15 to about 40 mol % of recurring units derived from acrylamide, methacrylamide, or a mixture thereof, and from about 5 to about 30 mol % and typically about 10 to about 30 mol % of recurring units derived from methacrylic acid. Other hydrophilic monomers, such as hydroxyethyl methacrylate, may be used in place of some or all of the methacrylamide. Other alkaline soluble monomers, such as acrylic acid, may be used in place of some or all of the methacrylic acid. Optionally, these polymers can also include recurring units derived from (meth)acrylonitrile or N-[2-(2-oxo-1-imidazolidinyl)ethyl]-methacrylamide.

The bakeable inner layers described in WO 2005/018934 (Kitson et al.) and U.S. Pat. No. 6,893,783 (Kitson et al.) may also be used.

Useful first polymeric binders can comprise, in polymerized form, from about 5 mol % to about 30 mol % (typically from about 10 mol % to about 30 mol % of recurring units) derived from an ethylenically unsaturated polymerizable monomer having a carboxy group (such as acrylic acid, methacrylic acid, itaconic acid, and other similar monomers known in the art (acrylic acid and methacrylic acid are preferred), from about 20 mol % to about 75 mol % (typically from about 35 mol % to about 60 mol %) of recurring units derived from N-phenylmaleimide, N-cyclohexylmaleimide, or a mixture thereof, optionally, from about 5 mol % to about 50 mol % (typically when present from about 15 mol % to about 40 mol %) of recurring units derived from methacrylamide, and from about 3 mol % to about 50 mol % (typically from about 10 mol % to about 40 mol % of one or more recurring units derived from monomer compounds of the following Structure (IV):

CH₂═C(R₂)—C(═O)—NH—CH₂—OR₁ (IV)

wherein R₁ is a C₁ to C₁₂ alkyl, phenyl, C₁ to C₁₂ substituted phenyl, C₁ to C₁₂ aralkyl, or Si(CH₃)₃, and R₂ is hydrogen or methyl. Methods of preparation of certain of these polymeric materials are disclosed in U.S. Pat. No. 6,475,692 (Jarek).

The first polymeric binder useful in the inner layer can also be hydroxy-containing polymeric material composed of recurring units derived from two or more ethylenically unsaturated monomers wherein from about 1 to about 50 mol % (typically from about 10 to about 40 mol %) of the recurring units are derived from on or more of the monomers represented by the following Structure (V′):

CH₂═C(R₃)C(═O)NR₄(CR₅R₆)ₘOH (V′)

wherein R₃, R_{4,} R₅, R₆ are independently hydrogen, substituted or unsubstituted lower alkyl having 1 to 10 carbon atoms (such as methyl, chloromethyl, ethyl, iso-propyl, t-butyl, and n-decyl), or substituted or unsubstituted phenyl, and m is 1 to 20.

Some embodiments of hydroxy-containing first polymeric binders can be represented by the following Structure (VI):

-(A)ₓ-(B)_{y}-(C)_{z}— (VI)

wherein A represents recurring units represented by the following Structure (VI-A):

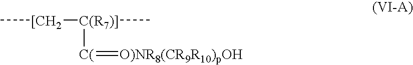

wherein R₇ through R₁₀ and p are as defined the same as R₃ through R₆ and m noted above for Structure (V′).

In Structure (VI), B represents recurring units comprising acidic functionality or an N-maleimide group, and C represents recurring units different from A and B, x is from about 1 to about 50 mol % (typically from about 10 to about 40 mol %), y is from about 40 to about 90 mol % (typically from about 40 to about 70 mol %), and z is 0 to about 70 mol % (typically from 0 to about 50 mol %), based on total recurring units.

In some embodiments of Structure (VI):

A represents recurring units derived from one or both of N-hydroxymethyl acrylamide and N-hydroxymethyl methacrylamide,

B represents recurring units derived from one or more of N-phenylmaleimide, N-cyclohexylmaleimide, N-benzylmaleimide, N-(4-carboxyphenyl)maleimide, (meth)acrylic acid, and vinyl benzoic acid,

C represents recurring units derived from one or more of a styrenic monomer (such as styrene and derivatives thereof), meth(acrylate) ester, N-substituted (meth)acrylamide, maleic anhydride, (meth)acrylonitrile, allyl acrylate, and a compound represented by the following Structure (VI-C):

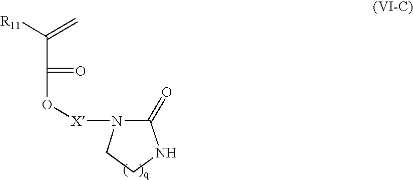

wherein R₁₁ is hydrogen, methyl, or halo, X′ is alkylene having 2 to 12 carbon atoms, q is 1 to 3, x is from about 10 to 40 mol %, y is from about 40 to about 70 mol %, and z is from 0 to about 50 mol %, all based on total recurring units.

In some embodiments for Structure VI, B represents recurring units derived from at least one of N-phenylmaleimide, N-cyclohexylmaleimide, N-benzylmaleimide, N-(4-carboxyphenyl)maleimide in an amount of from about 20 to about 50 mol %, and recurring units derived from at least one of (meth)acrylic acid and vinyl benzoic acid in an amount of from about 10 to about 30 mol %, based on total recurring units.

In such embodiments, C represents recurring units derived from methacrylamide, (meth)acrylonitrile, maleic anhydride, or

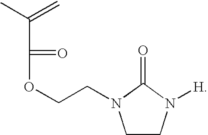

Still other useful first polymeric binders are addition or condensation polymers having a polymer backbone to which are attached pendant phosphoric acid groups (for example, derived from phosphate (meth)acrylate esters), pendant adamantyl groups, or both types of pendant groups. The pendant adamantyl groups are connected to the polymer backbone at least through a urea or urethane linking group but other linking groups can also be present. Useful first polymeric binders of this type are described in U.S. Pat. No. 7,247,418 (Saraiya et al.) that is incorporated herein by reference.

In referring to “phosphoric acid” groups, it is also intended to include the corresponding salts of the phosphoric acid, including but not limited to, alkali metal salts and ammonium salts. Any suitable positive counterion can be used with the pendant phosphoric acid groups as long as the counterion does not adversely affect the performance of the resulting polymer or other desired imaging properties.

Still other useful first polymeric binders comprise a backbone and have attached to the backbone the following Structure Q group:

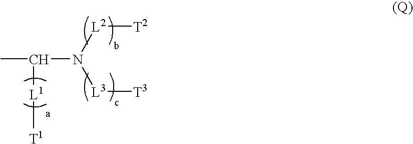

wherein L¹, L², and L³ independently represent linking groups, T¹, T², and T³ independently represent terminal groups, and a, b, and c are independently 0 or 1. Further details of such polymers are provided in Columns 20 and 21 of U.S. Pat. No. 7,247,418 (Saraiya et al.).

In some embodiments, the Structure Q group can be directly attached to an α-carbon atom in the polymer backbone, the α-carbon atom also having attached thereto an electron withdrawing group. In other embodiments, the Structure Q group is indirectly attached to the polymer backbone through a linking group.

The first polymeric binders can also be represented by the following Structure (X):

-(A)ₓ-(B)_{y}— (X)

wherein A represents recurring units derived from one or more ethylenically unsaturated polymerizable monomers that comprise the same or different Q groups, B represents recurring units derived from one or more different ethylenically unsaturated polymerizable monomers that do not comprise Q groups.

More particularly, the A recurring units in Structure X can be represented by the following Structure (Xa) or (Xb):

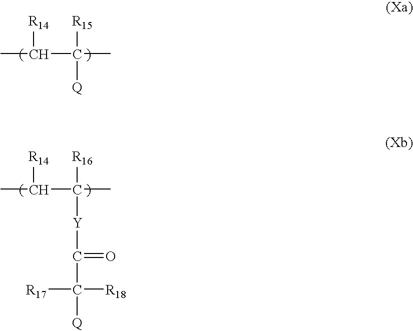

wherein R₁₄ and R₁₆ are independently hydrogen or a halo, substituted or unsubstituted alkyl having 1 to 7 carbon atoms (such as methyl, ethyl, n-propyl, iso-propyl, or benzyl), or a substituted or unsubstituted phenyl group. For example, R₁₄ and R₁₆ can be independently hydrogen or a methyl or halo group, and preferably they are independently hydrogen or methyl.

R₁₅ in Structure Xa is an electron withdrawing group as defined above including but are not limited to, cyano, nitro, substituted or unsubstituted aryl groups having 6 to 10 carbon atoms in the carbocyclic ring, substituted or unsubstituted heteroaryl groups having 5 to 10 carbon, sulfur, oxygen, or nitrogen atoms in the heteroaromatic ring, —C(═O)OR₂₀, and —C(═O)R₂₀ groups wherein R₂₀ is hydrogen or a substituted or unsubstituted alkyl having 1 to 4 carbon atoms (such as methyl, ethyl, n-propyl, t-butyl), a substituted or unsubstituted cycloalkyl (such as a substituted or unsubstituted cyclohexyl), or a substituted or unsubstituted aryl group (such as substituted or unsubstituted phenyl). The cyano, nitro, —C(═O)OR₂₀, and —C(═O)R₂₀ groups are useful and cyano, —C(═O)CH₃, and —C(═O)OCH₃ are more useful.

R₁₇ and R₁₈ in Structure (Xb) are independently hydrogen or a substituted or unsubstituted alkyl group having 1 to 6 carbon atoms (such as such as methyl, ethyl, n-propyl, t-butyl, n-hexyl), substituted or unsubstituted cycloalkyl having 5 or 6 carbon atoms (such as cyclohexyl), a substituted or unsubstituted aryl group having 6 to 10 carbon atoms (such as phenyl, 4-methylphenyl, and naphthyl), or a —C(═O)R₁₉ group wherein R₁₉ is a substituted or unsubstituted alkyl group (as defined for R₁₇ and R₁₈), a substituted or unsubstituted alkenyl group having 2 to 8 carbon atoms (such as ethenyl and 1,2-propenyl), a substituted or unsubstituted cycloalkyl group (as defined above for R₁₇ and R₁₈), or a substituted or unsubstituted aryl group (as defined above for R₁₇ and R₁₈). Preferably, R₁₇ and R₁₈ are independently hydrogen or a substituted or unsubstituted alkyl, cycloalkyl, aryl, or —C(═O)R₁₉ groups as defined above wherein R₁₉ is an alkyl having 1 to 4 carbon atoms.

In Structure (Xb), Y is a direct bond or a divalent linking group. Useful divalent linking groups include but are not limited to oxy, thio, —NR₂₁—, substituted or unsubstituted alkylene, substituted or unsubstituted phenylene, substituted or unsubstituted heterocyclylene, —C(═O)—, and —C(═O)O— groups, or a combination thereof wherein R₂₁ is hydrogen or a substituted or unsubstituted alkyl, substituted or unsubstituted cycloalkyl, or substituted or unsubstituted aryl group, as defined above for R₁₇ and R₁₈. For example, Y is a direct bond or an oxy, —C(═O)O—, —C(═O)OCH₂CH₂O—, or —C(═O)CH₂CH₂OC(═O)CH₂— group.

In Structure (X), x is from about 1 to about 70 mol %, and y is from about 30 to about 99 mol %, based on total recurring units. More typically, x is from about 5 to about 50 mol % and y is from about 50 to about 95 mol %, based on total recurring units.

Also in Structure (X), B can represent recurring units derived from a wide variety of ethylenically unsaturated polymerizable monomers. Particularly useful recurring units are derived from one or more N-substituted maleimides, N-substituted (meth)acrylamides, unsubstituted (meth)acrylamides, (meth)acrylonitriles, or vinyl monomers having an acidic group, and more preferably from one or more N-phenylmaleimides, N-cyclohexylmaleimides, N-benzylmaleimides, N-(4-carboxyphenyl)maleimides, (meth)acrylic acids, vinyl benzoic acids, (meth)acrylamides, and (meth)acrylonitriles. Several of these monomers can be copolymerized to provide multiple types of B recurring units. Useful combinations of B recurring units include those derived from two or more of methacrylic acid, methacrylamide, and N-phenylmaleimide.

The first polymeric binders are the predominant polymeric materials in the inner layer. That is, they comprise more than 50% and up to 100% (dry weight) of the total polymeric materials in the inner layer. However, the inner layer may also comprise one or more primary additional polymeric materials, provided these primary additional polymeric materials do not adversely affect the chemical resistance and solubility properties of the inner layer.

Useful primary additional polymeric materials include copolymers that comprises from about 1 to about 30 mole % of recurring units derived from N-phenylmaleimide, from about 1 to about 30 mole % of recurring units derived from methacrylamide, from about 20 to about 75 mole % of recurring units derived from acrylonitrile, and from about 20 to about 75 mole % of recurring units derived from one or more monomers of the Structure (XI):

CH₂═C(R₂₃)—CO₂—CH₂CH₂—NH—CO—NH-p-C₆H₄—R₂₂ (XI)

wherein R₂₂ is OH, COOH, or SO₂NH₂, and R₂₃ is H or methyl, and, optionally, from about 1 to about 30 mole % from about 3 to about 20 mole % of recurring units derived from one or more monomers of the Structure (XII):

CH₂═C(R₂₅)—CO—NH-p-C₆H₄—R₂₄ (XII)

wherein R₂₄ is OH, COOH, or SO₂NH₂, and R₂₅ is H or methyl.

The inner layer may also comprise one or more secondary additional polymeric materials that are resins having activated methylol and/or activated alkylated methylol groups. These “secondary additional polymeric materials” in the inner layer should not be confused with the “second polymeric binder” used in the outer layer.

The secondary additional polymeric materials can include, for example resole resins and their alkylated analogs, methylol melamine resins and their alkylated analogs (for example melamine-formaldehyde resins), methylol glycoluril resins and alkylated analogs (for example, glycoluril-formaldehyde resins), thiourea-formaldehyde resins, guanamine-formaldehyde resins, and benzoguanamine-formaldehyde resins. Commercially available melamine-formaldehyde resins and glycoluril-formaldehyde resins include, for example, CYMEL® resins (Dyno Cyanamid) and NIKALAC® resins (Sanwa Chemical).

The resin having activated methylol and/or activated alkylated methylol groups is preferably a resole resin or a mixture of resole resins. Resole resins are well known to those skilled in the art. They are prepared by reaction of a phenol with an aldehyde under basic conditions using an excess of phenol. Commercially available resole resins include, for example, GP649D99 resole (Georgia Pacific) and BKS-5928 resole resin (Union Carbide).

Useful secondary additional polymeric materials can also include copolymers that comprise from about 25 to about 75 mole % of recurring units derived from N-phenylmaleimide, from about 10 to about 50 mole % of recurring units derived from methacrylamide, and from about 5 to about 30 mole % of recurring units derived from methacrylic acid. These secondary additional copolymers are disclosed in U.S. Pat. Nos. 6,294,311 and 6,528,228 (both noted above).

The first polymeric binders described above generally comprise at least 50 weight % and typically from about 60 to about 90 weight % and this amount can be varied depending upon what other polymers and chemical components are present. Any primary and secondary additional polymeric materials (such as a novolak, resole, or copolymers noted above) can be present in an amount of from about 5 to about 45 weight %.

The inner layer can also include other components such as surfactants, dispersing aids, humectants, biocides, viscosity builders, drying agents, defoamers, preservatives, antioxidants, and colorants.

The inner layer generally has a dry coating coverage of from about 0.5 to about 2.5 g/m² and typically from about 1 to about 2 g/m².

Outer Layer:

The outer layer of the lithographic printing plate precursor is disposed over the inner layer and in most embodiments there are no intermediate layers between the inner and outer layers. The outer layer is usually substantially free of infrared radiation absorbing compounds, meaning that none of these compounds are purposely incorporated therein and insubstantial amounts diffuse into it from other layers.

The one or more second polymeric binders are present in the outer layer at a dry coverage of from about 15 to 100 weight %, typically from about 70 to about 98 weight %.

The second polymeric binders used in the outer layer are generally insoluble in the gum (defined below) prior to infrared radiation exposure and soluble in that gum after such thermal exposure. The second polymeric binders can be chosen at least from one or more of the following seven classes of polymers:

a) novolak resins, resole resins, branched or unbranched polyhydroxystyrenes (or polyvinyl phenols), polyvinyl acetals with pendant phenol groups, and any combination thereof,

b) polymers having recurring units derived from one or more monomers of group (a) that is selected from the group consisting norbornene, tetracyclododecene, and mixtures thereof, and recurring units derived from one or more monomers of group (b) that is selected from the group consisting of maleic anhydride, maleimide, N-phenyl maleimide, N-benzyl maleimide, N-cyclohexyl maleimide, and mixtures thereof,

c) copolymers derived from maleic anhydride and monomers of the formula CH₂═CH(C₆H₄R¹) and mixtures thereof in which R¹ is hydrogen, halogen, hydroxyl, cyano, sulfonamide, alkyl of 1 to 6 carbon atoms, alkoxyl of 1 to 6 carbon atoms, acyl of 1 to 7 carbon atoms, acyloxy of 1 to 7 carbon atoms, carboalkoxy of 1 to 7 carbon atoms, or a mixture thereof,

d) copolymers derived from methyl methacrylate and a carboxylic acid containing monomer or a mixture of carboxylic acid containing monomers,

e) polymers having an —X—C(=T)-NR—S(═O)₂— moiety that is attached to the polymer backbone, wherein —X— is an oxy or —NR′— group, T is O or S, R and R′ are independently hydrogen, halo, or an alkyl group having 1 to 6 carbon atoms, and

f) polymers having recurring units represented by the following Structure (I-F) or (II-F):

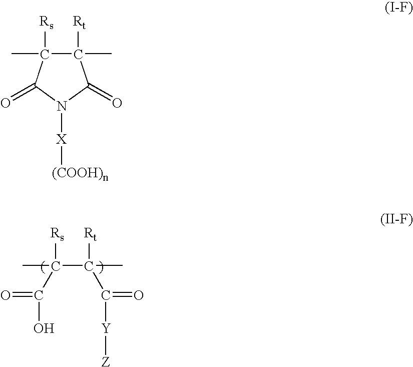

wherein n is 1 to 3, Rₛ and Rₜ are independently hydrogen or an alkyl or halo group, X is a multivalent linking group, Y is oxy or —NR— wherein R is hydrogen or an alkyl or aryl group, and Z is a monovalent organic group.

Class a) Polymers:

Examples of Class a) polymers include but are not limited to, poly(hydroxystyrenes), novolak resins, resole resins, poly(vinyl acetals) having pendant phenolic groups, and mixtures of any of these resins (such as mixtures of one or more novolak resins and one or more resole resins). The novolak resins are most preferred.

Generally, such resins have a number average molecular weight of at least 3,000 and up to 200,000, and typically from about 6,000 to about 100,000, as determined using conventional procedures. Most of these types of resins are commercially available or prepared using known reactants and procedures. For example, the novolak resins can be prepared by the condensation reaction of a phenol with an aldehyde in the presence of an acid catalyst. Typical novolak resins include but are not limited to, phenol-formaldehyde resins, cresol-formaldehyde resins, phenol-cresol-formaldehyde resins, p-t-butylphenol-formaldehyde resins, and pyrogallol-acetone resins, such as novolak resins prepared from reacting m-cresol or a m,p-cresol mixture with formaldehyde using conventional conditions. For example, some useful novolak resins include but are not limited to, xylenol-cresol resins, for example, SPN400, SPN420, SPN460, and VPN1100 (that are available from AZ Electronics) and EP25D40G and EP25D50G that have higher molecular weights, such as at least 4,000.

Other useful Class a) resins include polyvinyl compounds having phenolic hydroxyl groups, such as poly(hydroxystyrenes) and copolymers containing recurring units of a hydroxystyrene and polymers and copolymers containing recurring units of substituted hydroxystyrenes.

Also useful are branched poly(hydroxystyrenes) having multiple branched hydroxystyrene recurring units derived from 4-hydroxystyrene as described for example in U.S. Pat. No. 5,554,719 (Sounik) and U.S. Pat. No. 6,551,738 (Ohsawa et al.), and U.S. Published Patent Applications 2003/0050191 (Bhatt et al.) and 2005/0051053 (Wisnudel et al.), and in copending and commonly assigned U.S. patent application Ser. No. 11/474,020 (filed Jun. 23, 2006 by Levanon et al.), that is incorporated herein by reference. For example, such branched hydroxystyrene polymers comprise recurring units derived from a hydroxystyrene, such as from 4-hydroxystyrene, which recurring units are further substituted with repeating hydroxystyrene units (such as 4-hydroxystyrene units) positioned ortho to the hydroxy group. These branched polymers can have a weight average molecular weight (M_{w}) of from about 1,000 to about 30,000, typically from about 1,000 to about 10,000, or from about 3,000 to about 7,000. In addition, they may have a polydispersity less than 2 and typically from about 1.5 to about 1.9. The branched poly(hydroxystyrenes) can be homopolymers or copolymers with non-branched hydroxystyrene recurring units.

Some useful poly(hydroxystyrenes) are described in EP 1,669,803A (Barclay et al.).

Other useful polymeric binders are modified novolak or resole resins that are represented in the Structure described above.

In some embodiments, the polymeric binder comprises recurring units represented by Structure (POLYMER) wherein a is from about 92 to about 98 mol %, b is from about 2 to about 8 mol % and Z is —C(═O)OH, and is present at a dry coverage of from about 15 to 100 weight % based on the total dry weight of the layer.

Class b) Polymers:

Examples of Class b) polymers include but are not limited to the co-polymers derived at least in part from group (a₁) monomer described below and group (b₁) monomer described below with at least about 15 mol % of recurring units from the group (a₁) monomers and at least about 10 mol % of recurring units from the group (b₁) monomers. When electron deficient olefins, such as maleic anhydride or a maleimide are used as group (b₁) monomer, 1:1 alternating co-polymers (that is, 50 mol % of the group (a₁) monomer and 50 mol % of the group (b₁)) are typically produced.

Group (a₁) monomers include norbornene and norbornene derivatives such as:

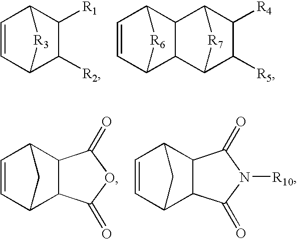

and mixtures thereof

Group (b₁) monomers include:

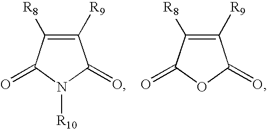

acrylonitrile, methacrylonitrile, styrene, hydroxystyrene, CH(R₁₁)CH(CO₂R₁₂), CH(R₁₁)CH(CON(R₁₂)₂), CH₂CH(OR₁₂), and mixtures thereof R₁, R₂, R₄, and R₅ are each independently hydrogen, phenyl, substituted phenyl, halogen, alkyl of 1 to 6 carbon atoms, alkoxy of 1 to 6 carbon atoms, acyl of 1 to 7 carbon atoms, acyloxy of 1 to 7 carbon atoms, carboalkoxy of 1 to 7 carbon atoms, or a mixture thereof. Substituted phenyl groups include, for example, 2-methylphenyl, 3-methylphenyl, 4-methylphenyl, 4-t-butylphenyl, 4-methoxyphenyl, 3-ethoxyphenyl, 4-cyanophenyl, 4-chlorophenyl, 4-fluorophenyl, 4-acetoxyphenyl, 4-carboxyphenyl, 4-carboxymethylphenyl, 4-carboxyethylphenyl, 3,5-dichlorophenyl, and 2,4,6-trimethylphenyl. Halogen includes fluoro, chloro, and bromo. Examples are CH₃CO— (acetyl), CH₃CH₂CO—, CH₃(CH₂)₂CO—, CH₃(CH₂)₃CO—, (CH₃)₃CCO—, and (CH₃)₃CCH₂CO—. Acyloxy groups of 1 to 7 carbon atoms are —OC(O)R groups in which R is an alkyl group of 1 to 6 carbon atoms, such as are listed above. Examples are H₃CC(═O)O—(acetyloxy), CH₃CH₂C(═O)O—, CH₃(CH₂)₂C(═O)O—, CH₃(CH₂)₃C(═O)O—, (CH₃)₃CC(═O)O—, and (CH₃)₃CCH₂C(═O)O—. Carboalkoxy groups of 1 to 7 carbon atoms are —CO₂R groups in which R is an alkyl group of 1 to 6 carbon atoms, such as are listed above. Examples are —C(═O)OCH₃, (carbomethoxy), —C(═O)OCH₂CH₃, —C(═O)O(CH₂)₂CH₃, —C(═O)O(CH₂)₃CH₃, —C(═O)OC(CH₃)₃ (carbo-t-butoxy), —C(═O)OCH₂C(CH₃)₃, —C(═O)O(CH₂)₄CH₃, and —C(═O)O(CH₂)₅CH₃. R₃, R₆, and R₇ are each —CH₂—. Each R₈ and R₉ is each independently hydrogen or methyl, or a mixture thereof, typically hydrogen. R₁₀ is hydrogen, hydroxyl, alkyl of 1 to 6 carbon atoms, phenyl, substituted phenyl, benzyl, or a mixture thereof. Each R₁₁ is independently hydrogen, methyl, or a mixture thereof. Each R₁₂ is independently hydrogen, alkyl of 1 to 6 carbon atoms, phenyl or a mixture thereof, typically hydrogen, methyl, or a mixture thereof.

More specifically, group (a₁) monomers include but are not limited to, norbornene (bicyclo[2.2.1]hept-2-ene) and its derivatives, such as methyl 5-norbornene-2-carboxylate, t-butyl 5-norbornene-2-carboxylate, and other esters of 5-norbornene-2-carboxylic acid; cis-5-norbornene-endo-2,3-dicarboxylic anhydride and the corresponding imides, such as the N-methyl, N-hydroxyl, N-phenyl, N-cyclohexyl, and the N-benzyl imides; tetracyclododecene (tetracyclo[4.4.0.1^{2,5}.1^{7,10}]dodec-3-ene) and its derivatives, such as the esters of (tetracyclo[4.4.0.1^{2,5}.1^{7,10}]dodec-3-ene-8-carboxylic acid, for example methyl (tetracyclo[4.4.0.1^{2,5}.1^{7,10}]dodec-3-ene)-8-carboxylate, ethyl (tetracyclo[4.4.0.1^{2,5}.1^{7,10}]dodec-3-ene)-8-carboxylate, and t-butyl (tetracyclo[4.4.0.1^{2,5}.1^{7,10}]dodec-3-ene)-8-carboxylate; (tetracyclo[4.4.0.1^{2,5}.1^{7,10}]dodec-3-ene-endo-8,9-dicarboxylic acid and its corresponding imides, such as the N-methyl, N-hydroxyl, N-phenyl, N-cyclohexyl, and the N-benzyl imides; and mixtures thereof.

Group (b₁) include but are not limited to, acrylonitrile, methacrylonitrile, hydroxystyrene, acrylic acid esters such as methyl acrylate, ethyl acrylate, propyl acrylate, butyl acrylate, and phenyl acrylate; methacrylic acid esters such as methyl methacrylate, ethyl methacrylate, propyl methacrylate, butyl methacrylate, and phenyl methacrylate; methacrylamides and acrylamides, such as methacrylamide, acrylamide, N,N-dimethyl acrylamide, N,N-dimethyl methacrylamide, and the acrylamide and methacrylamide of p-aminobenzoic acid; maleic anhydride; maleic acid imides, such as N-phenylmaleimide, N-cyclohexylmaleimide, N-benzylmaleimide, N-methylmaleimide, N-hydroxylmaleimide; vinyl ethers, such as methyl vinyl ether and ethyl vinyl ether; and mixtures thereof.

Further details the Class b) polymers and methods of making them are provided in U.S. Pat. No. 6,969,570 (Kitson).

Class c) Polymers:

Examples of Class c) polymers include but are not limited to, copolymers derived at least in part from maleic anhydride and styrene or a substituted styrene or a mixture of substituted styrenes (styrene derivatives). Recurring units derived from maleic anhydride typically comprises from about 1 to about 50 mol % and more likely from about 15 to about 50 mol % of the co-polymer.

Typically, the styrene and substituted styrene styrenes can be represented by the formula CH₂═CH(C₆H₄R¹). The substituent R¹ may be o-, m-, or p- to the vinyl (CH₂═CH—) group. R¹ can be hydrogen, halogen, hydroxyl, cyano, sulfonamide, alkyl of 1 to 6 carbon atoms, alkoxy of 1 to 6 carbon atoms, acyl of 1 to 7 carbon atoms, acyloxy of 1 to 7 carbon atoms, carboalkoxy of 1 to 7 carbon atoms, or a mixture thereof. Halogen includes fluoro, chloro, and bromo. An example of a sulfonamide group is —SO₂NH₂. Acyl groups of 1 to 7 carbon atoms are —C(═O)R groups in which R is an alkyl group of 1 to 6 carbon atoms, such as are listed above. Examples are CH₃CO— (acetyl), CH₃CH₂CO—, CH₃(CH₂)₂CO—, CH₃(CH₂)₃CO—, (CH₃)₃CCO—, and (CH₃)₃CCH₂CO—. Acyloxy groups of 1 to 7 carbon atoms are —OC(O)R groups in which R is an alkyl group of 1 to 6 carbon atoms, such as are listed above. Examples are H₃CC(═O)O— (acetyloxy), CH₃CH₂C(═O)O—, CH₃(CH₂)₂C(═O)O—, CH₃(CH₂)₃C(═O)O—, (CH₃)₃CC(═O)O—, and (CH₃)₃CCH₂C(═O)O—. Carboalkoxy groups of 1 to 7 carbon atoms are —CO₂R groups in which R is an alkyl group of 1 to 6 carbon atoms, such as are listed above. Examples are —C(═O)OCH₃, (carbomethoxy), —C(═O)OCH₂CH₃ (carboethoxy), —C(═O)O(CH₂)₂CH₃, —C(═O)O(CH₂)₃CH₃, —C(═O)OC(CH₃)₃ (carbo-t-butoxy), —C(═O)OCH₂C(CH₃)₃, —C(═O)O(CH₂)₄CH₃, and —C(═O)O(CH₂)₅CH₃. A useful monomer is styrene wherein R₁ is hydrogen in the noted formula.

Recurring units derived from additional monomers, such as acrylate and methacrylate monomers (such as methyl acrylate, ethyl acrylate, ethyl methacrylate, butyl acrylate, and butyl methacrylate), acrylonitrile; methacrylonitrile, methacrylamides (such as methacrylamide and N,N-dimethyl methacrylamide), and acrylamides (such as acrylamide and N,N-dimethyl acrylamide), may also be present, but are not required.

Further details of Class c) copolymers and methods of making them are provided for example in U.S. Patent Application Publication 2007/0065737 (Kitson et al.).

Class d) Polymers:

Examples of Class d) polymers include but are not limited to, copolymers are derived at least in part from methyl methacrylate and a carboxylic acid containing monomer, typically a carboxylic acid containing monomer of 14 or fewer carbon atoms, more typically a carboxylic acid containing monomer of 9 or fewer carbon atoms. A mixture of carboxylic acid containing monomers may also be used. Typical carboxylic acid containing monomers are acrylic acid, methacrylic acid, 3-vinyl benzoic acid, 4-vinyl benzoic acid, itaconic acid, maleic acid, and monomers formed by the reaction of a hydroxyl containing monomer, such as 2-hydroxyethyl acrylate or 2-hydroxyethyl methacrylate with a cyclic anhydride such as succinic anhydride or phthalic anhydride. A particularly useful carboxylic acid containing monomer is methacrylic acid.

The molar ratio of recurring units derived from methyl methacrylate to the recurring units derived from carboxylic acid containing monomer(s) is generally from about 80:20 to about 98:2 and typically from about 90:10 to about 95:5.

Recurring units derived from additional monomers, such as acrylate and other methacrylate monomers (such as methyl acrylate, ethyl acrylate, ethyl methacrylate, butyl acrylate, and butyl methacrylate), maleic anhydride, vinyl ethers (such as methyl vinyl ether), acrylonitrile, methacrylonitrile, methacrylamides (such as methacrylamide and N, N-dimethyl methacrylamide), and acrylamides (such as acrylamide and N,N-dimethyl acrylamide), may also be present, but are not required. Typically, the copolymer consists essentially of the methyl methacrylate and the carboxylic acid containing monomer or mixture of carboxylic acid containing monomers. The molecular weights of the Class d) copolymers are generally less than 200,000. Further details of the Class d) copolymers and methods of making them are also provided for example in U.S. Patent Application Publication 2007/0065737 (Kitson et al.).

Class e) Polymers:

Examples of Class e) polymers include but are not limited to, polymeric binders having a pKa of from about 6 to about 9 (typically from about 6 to about 8) that comprise a variety of groups (usually groups pendant to the polymer backbone) that are either directly or indirectly attached to the polymer backbone in sufficient quantity that will provide the desired pKa including, but not limited to, mercapto groups, sulfonamido groups, and N-substituted sulfonamido groups (including but not limited to, alkyl, acyl, alkoxycarbonyl, alkylaminocarbonyl, and β-keto ester substituted sulfonamido groups), α-cyano esters, α-cyano ketones, beta-diketones, and α-nitro esters. The unsubstituted and substituted sulfonamido groups are useful. These polymers can also comprise a mixture of the noted pendant groups along the polymer backbone.

More particularly, each of the Class e) polymers can comprise a polymer backbone and an —X—C(=T)-NR—S(=O)₂— moiety that is attached to and along the polymer backbone, wherein —X— is an oxy (—O—) or —NR′— group, T is O (forming an oxo group) or S (forming a thioxo group), and R and R′ are independently hydrogen, halo, or a substituted or unsubstituted alkyl group having 1 to 6 carbon atoms. For example, R is hydrogen, T is O, and X is an oxy or —NH— group.

In some embodiments, the Class e) polymers comprise one or more acrylic resins that are derived from one or more ethylenically unsaturated polymerizable monomers, at least one of which monomers comprises pendant —X‘3C(=T)-NR—S(═O)₂—R³ groups that are defined below.

More particularly, the Class e) polymers can be represented by the following Structure (E):

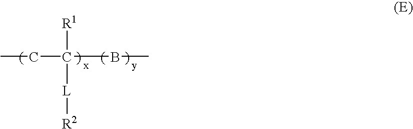

wherein R¹ is hydrogen, a substituted or unsubstituted alkyl group having 1 to 6 carbon atoms (such as methyl, ethyl, chloromethyl, iso-propyl and benzyl), or a halo group (such as fluoro, chloro, or bromo). For example, R¹ is hydrogen or a substituted or unsubstituted methyl or chloro group, or it is hydrogen or unsubstituted methyl.

R² represents the —X—C(=T)-NR—S(═O)₂—R³ group wherein X, T, and R are as defined above, and R³ is a substituted or unsubstituted aliphatic group or a substituted or unsubstituted aryl group directly attached to —S(═O)₂— through a carbon atom. More particularly, R³ can represent a substituted or unsubstituted alkyl group having 1 to 12 carbon atoms, a substituted or unsubstituted cycloalkylene group having 5 to 10 carbon atoms in the ring, a substituted or unsubstituted aryl group having 6 to 10 carbon atoms in the ring, or a substituted or unsubstituted heterocyclyl group, or any combinations of such groups that are linked directly together, or linked together with oxy, carbonyl, amido, thio, or other groups that would be readily apparent to one skilled in the art. For example, R³ is a substituted or unsubstituted phenyl group.

L is a direct bond or a linking group, including but not limited to substituted or unsubstituted alkylene, cycloalkylene, arylene, a divalent heterocyclic, carbonyloxy, thio, oxy, or amido groups, or combinations thereof. The substituted or unsubstituted alkylene groups can have 1 to 6 carbon atoms (such as methylene, 1,2-ethylene, 1,1-ethylene, n-propylene, iso-propylene, t-butylene, n-butylene, and n-hexylene groups), substituted cycloalkylene groups can have 5 to 7 carbon atoms in the cyclic ring (such as cyclopentylene and 1,4-cyclohexylene), the substituted or unsubstituted arylene groups can have 6 to 10 carbon atoms in the aromatic ring (such as 1,4-phenylene, naphthylene, 2-methyl-1,4-phenylene, and 4-chloro-1,3-phenylene groups), and the substituted or unsubstituted, aromatic or non-aromatic divalent heterocyclic groups can have 5 to 10 carbon and one or more heteroatoms (nitrogen, oxygen, or sulfur atoms) in the cyclic ring (such as pyridylene, pyrazylene, pyrimidylene, or thiazolylene groups). Combinations of two or more of these divalent linking groups can be used.

It is useful that L represent a carboxylic acid ester group such as a substituted or unsubstituted —C(═O)O-alkylene, —C(═O)O-alkylene-phenylene-, or —C(═O)O-phenylene group wherein alkylene has 1 to 4 carbon atoms. More preferably, L is a —C(═O)O-alkylene, —C(═O)O-alkylene-phenylene-, or —C(═O)O— phenylene group and most preferably, it is a -C(═O)O-alkylene group wherein the alkylene group has 1 or 2 carbon atoms.

In Structure (E) noted above, B represents recurring units derived from one or more ethylenically unsaturated polymerizable monomers that do not contain an R² group, including but not limited to, recurring units derived from a (meth)acrylate, (meth)acrylamide, vinyl ether, vinyl ester, vinyl ketone, olefin, unsaturated imide (such as maleimide), N-vinyl pyrrolidone, N-vinyl carbazole, 4-vinyl pyridine, (meth)acrylonitrile, unsaturated anhydride, or styrenic monomer. Preferably, the B recurring units are derived from one or more (meth)acrylates, styrenic monomers, (meth)acrylonitriles, (meth)acrylamides, or combinations thereof. Mixtures of monomers can be used to provide a mixture of recurring units represented by “B” in Structure (E).

In Structure (E), x is from about 20 to 85 weight %, and y is from about 15 to about 80 weight %.

Examples of useful monomers containing R² groups that are useful for these polymeric binders are the following ethylenically unsaturated polymerizable monomers A-1 through A-6:

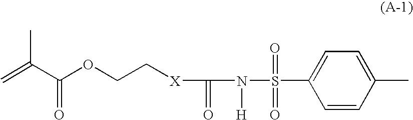

wherein X is as defined above,

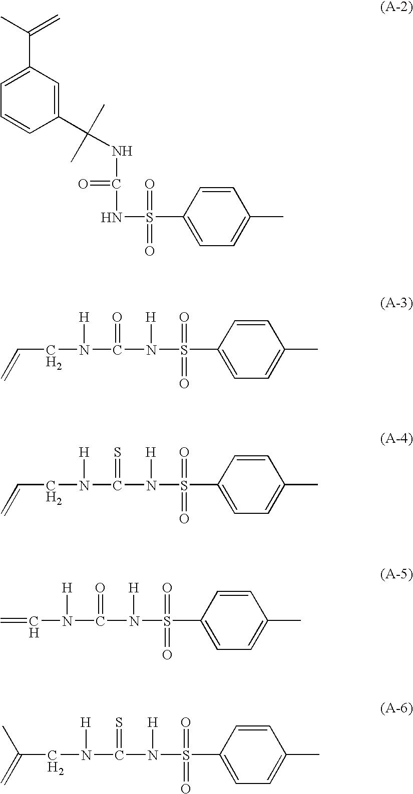

Further details of Class e) polymers and methods of making them are provided in U.S. Pat. No. 7,241,556 (Saraiya et al.).

Class f) Polymers:

Examples of Class f) polymers include but are not limited to, those described in U.S. Pat. No. 7,169,518 (Savariar-Hauck et al.) that also provides details about making these polymers. In particular, these polymeric binders comprise recurring units having pendant carboxy groups that are generally represented by the following Structure (I-F) or (II-F), which recurring units generally comprise at least 3 mol % of the total recurring units in the polymeric binder:

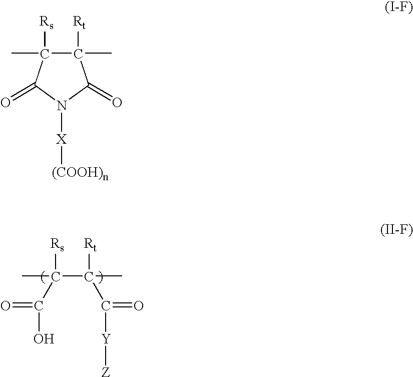

wherein n is 1 to 3 (typically 1 or 2). Rₛ and Rₜ are independently hydrogen or a substituted or unsubstituted alkyl group having 1 to 7 carbon atoms (such as methyl, ethyl, t-butyl, or benzyl), or a halo group (such as chloro or bromo). For example, Rₛ and Rₜ are independently hydrogen or a substituted or unsubstituted methyl group or chloro group.

X is a multivalent linking group including, but not limited to multivalent aliphatic and aromatic linking groups, and combinations thereof. In most embodiments, X is a divalent linking group. Such groups can include alkylene, arylene, alkylenearylene, arylenealkylene, alkyleneoxyalkylene, aryleneoxyarylene, and alkyleneoxyarylene groups, all of which can be unsubstituted or substituted with one or more substituents that do not adversely affect the performance of the second polymeric binder. For example, X is a substituted or unsubstituted phenylene group, especially when n is 1.

In Structure (II-F), Y is oxy or —NR— wherein R is hydrogen or a substituted or unsubstituted alkyl group having 1 to 10 carbon atoms (such as methyl, ethyl, iso-propyl, n-hexyl, and benzyl groups) or substituted or unsubstituted aryl group (such as a phenyl group).

Also in Structure (II-F), Z is a monovalent organic group including but not limited to, a monovalent aliphatic or aromatic group, or a combination thereof. Such groups are defined similar to the multivalent groups described above for X but can also include arylene or alkylene groups, or combinations thereof, with or without carbonyl groups [—C(═O)—] or amido groups (—NH—) groups, or combinations thereof. For example, useful Z groups include —R′—NHC(═O)R″ groups wherein R′ is a substituted or unsubstituted alkylene group having 2 to 6 carbon atoms (such as ethylene and iso-propylene), and R″ is a substituted or unsubstituted alkyl group having 1 to about 10 carbon atoms (such as methyl, methoxymethyl, ethyl, iso-propyl, n-hexyl, and benzyl groups) or a substituted or unsubstituted aryl group (such as a phenyl group). One useful Z group is a —CH₂CH₂NHC(═O)-phenyl group.

Z can also be a substituted or unsubstituted alkyl group having 1 to 10 carbon atoms (such as methyl, ethyl, iso-propyl, t-butyl, n-hexyl, and benzyl groups). Useful alkyl groups for Z include those having 1 to 8 carbon atoms (including straight-chain and branched butyl groups).

The Class f) polymeric binders generally has an acid number of at least 20 mg KOH/g and typically of from about 25 to about 45 mg KOH/g, and a number average molecular weight of at least 1,000 and up to 250,000, and typically from about 10,000 to about 150,000 as measured using known techniques.

The Class f) polymeric binders can also be represented by the following Structure (III-F):

-(A)ₓ-(B)_{y}— (III-F)

wherein A represents recurring units defined by either Structure (I-F) or (II-F) or both Structures (I-F) and (II-F). Thus, multiple types of monomers can be used to provide the A recurring units. In Structure (III-F), x is about 3 to about 15 mol % and y is from about 85 to about 97 mol %.

B represents recurring units other than those represented by A. They can be derived from one or more ethylenically unsaturated polymerizable monomers that are capable of copolymerizing with the monomers from which the A recurring units are derived, including maleic acid anhydride. Representative useful monomers for the B recurring units include but are not limited to, (meth)acrylates, (meth)acrylamides, vinyl ethers, vinyl esters, vinyl ketones, olefins, unsaturated imides including N-maleimides, unsaturated anhydrides such as maleic anhydrides, N-vinyl pyrrolidone, N-vinyl carbazole, 4-vinyl pyridine, (meth)acrylonitriles, or styrenic monomers, or any combinations of these monomers. Specific monomers of these and similar classes are described for example, in paragraphs [0044] through [0054] of U.S. Patent Application Publication 2004/0137366 (corresponding to EP 1,433,594A).

For example, B represents recurring units for Structure (III-F) that are derived from one or more (meth)acrylates, (meth)acrylonitriles, N-phenylmaleimide, or (meth)acrylamides such as N-alkoxyalkyl methacrylamides, or combinations of two or more of such monomers. Some useful monomers from which B recurring units are derived include methyl methacrylate, styrene, ethylenically unsaturated polymerizable monomers having pendant cyclic urea groups, and combinations thereof.

The one or more polymeric binders (of any class) can be present in the outer layer at a dry coverage of from about 15 to 100 weight % and typically from about 30 to about 95 weight %.

In some embodiments, the lithographic printing plate precursor inner layer comprises a first polymeric binder that is a polymer derived at least in part from (meth)acrylamide, a polymer derived at least in part from a (meth)acrylonitrile, a polymer derived at least in part from an N-substituted cyclic imide, or a polymer derived at least in part from styrene or a styrene derivative, and

the outer layer comprises a second polymeric binder that is a copolymer derived from styrene and maleic anhydride or a polymer derived at least in part from monomer having a pendant —O—C(═O)—NH—S(═O)₂— methylphenyl group. For example, the second polymeric binder can have recurring units derived from the following monomer:

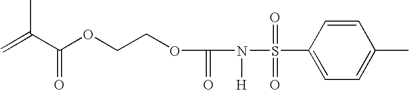

In addition, solubility-suppressing components are optionally incorporated into the outer layer. Such components are described above in relation to the single-layer positive-working lithographic printing plate precursors.

The outer layer generally also includes colorants. Useful colorants are described for example in U.S. Pat. No. 6,294,311 (noted above) including triarylmethane dyes such as ethyl violet, crystal violet, malachite green, brilliant green, Victoria blue B, Victoria blue R, and Victoria pure blue BO. These compounds can act as contrast dyes that distinguish the non-exposed regions from the exposed regions in the developed lithographic printing plate.

The imageable layer can further include a variety of additives including dispersing agents, humectants, biocides, plasticizers, surfactants for coatability or other properties, viscosity builders, contrast dyes or colorants to allow visualization of the written image, pH adjusters, drying agents, defoamers, preservatives, antioxidants, development aids, rheology modifiers, or combinations thereof, or any other addenda commonly used in the lithographic art, in conventional amounts.

The outer layer generally has a dry coating coverage of from about 0.2 to about 2 g/m² and typically from about 0.4 to about 1.5 g/m².

Intermediate drying steps may be used between applications of the various layer formulations to remove solvent(s) before coating other formulations. Drying steps may also help in preventing the mixing of the various layers.

There may be a separate layer that is between and in contact with the inner and outer layers to minimize migration of radiation absorbing compound(s) from the inner layer to the outer layer. This separate “barrier” layer generally comprises a third polymeric binder that is soluble in the gum. If this third polymeric binder is different from the first polymeric binder(s) in the inner layer, it is typically soluble in at least one organic solvent in which the inner layer first polymeric binders are insoluble. A useful third polymeric binder is a poly(vinyl alcohol).

Alternatively, there may be a separate layer between the inner and outer layers that contains the infrared radiation absorbing compound(s), which may also be present in the inner layer, or solely in the separate layer.

The multi-layer lithographic printing plate precursors can be prepared by sequentially applying the first of one or more imageable layer (for example, an inner layer) formulations over the surface of the hydrophilic substrate (and any other hydrophilic layers provided thereon). In the case of multi-layer precursors, an outer layer formulation is applied over the inner layer using conventional coating or lamination methods. It is important to avoid intermixing of the inner and outer layer formulations.

For example, a multi-layer lithographic printing plate precursor can be prepared with an inner layer comprising a first polymeric binder and a radiation absorbing compound, and

an ink receptive outer layer comprising a second polymeric binder that: (1) is different than the first polymeric binder, (2) is insoluble in the processing solution (defined below) before infrared radiation exposure, and (3) soluble in the processing solution after such exposure.

The layers can be applied by dispersing or dissolving the desired ingredients in a suitable coating solvent(s), and the resulting formulations are sequentially or simultaneously applied to the substrate using suitable equipment and procedures, such as spin coating, knife coating, gravure coating, die coating, slot coating, bar coating, wire rod coating, roller coating, or extrusion hopper coating. The formulations can also be applied by spraying onto a suitable support (such as an on-press printing cylinder).

The selection of solvents used to coat both the layers depends upon the nature of the polymeric binders used and other components in the formulations. For example, to prevent the inner and outer layer formulations from mixing or the inner layer from dissolving when the outer layer formulation is applied, the outer layer formulation should be coated from a solvent in which the first polymeric binder(s) of the inner layer are insoluble.

Generally, an inner layer formulation is coated out of a solvent mixture of methyl ethyl ketone (MEK), 1-methoxy-2-propyl acetate (PMA), γ-butyrolactone (BLO), and water, a mixture of MEK, BLO, water, and 1-methoxypropan-2-ol (also known as Dowanol® PM or PGME), a mixture of diethyl ketone (DEK), water, methyl lactate, and BLO, a mixture of DEK, water, and methyl lactate, or a mixture of methyl lactate, methanol, and dioxolane.

An outer layer formulation can be coated out of solvents or solvent mixtures that do not dissolve the inner layer. Typical solvents for this purpose include but are not limited to, butyl acetate, iso-butyl acetate, methyl iso-butyl ketone, DEK, 1-methoxy-2-propyl acetate (PMA), iso-propyl alcohol, PGME and mixtures thereof. Particularly useful is a mixture of DEK and represents poly(ethylene glycol) methyl ether methacrylate (PGMEA), or a mixture of DEK, PMA, and isopropyl alcohol (IPA).

Alternatively, the layers may be applied by extrusion coating methods from melt mixtures of the respective layer compositions. Typically, such melt mixtures contain no volatile organic solvents.

Intermediate drying steps may be used between applications of the various layer formulations to remove solvent(s) before coating other formulations. Drying steps may also help in preventing the mixing of the various layers.

After coating and drying the various layers, the lithographic printing plate precursors can be further “conditioned” with a heat treatment at from about 40 to about 90° C. for at least 4 hours (for example, at least 20 hours) under conditions that inhibit the removal of moisture from the dried layers. For example, the heat treatment is carried out at from about 50 to about 70° C. for at least 24 hours. During the heat treatment, the lithographic printing plate precursor is wrapped or encased in a water-impermeable sheet material to represent an effective barrier to moisture removal from the precursor, or the heat treatment of the precursor is carried out in an environment in which relative humidity is controlled to at least 25%. In addition, the water-impermeable sheet material can be sealed around the edges of the precursor, with the water-impermeable sheet material being a polymeric film or metal foil that is sealed around the edges of the precursor. Further details of such conditioning are provided for example, in U.S. Pat. No. 7,175,969 (Ray et al.).

In some embodiments, this heat treatment can be carried out with a stack comprising at least 100 of the same lithographic printing plate precursors, or when the precursor is in the form of a coil or web. While being conditioned in a stack, the individual precursors may be separated by suitable interleaving papers. Such papers are available from several commercial sources. The interleaving papers may be kept between the precursors after conditioning during packing and shipping and until they are used by the customer.

Representative methods for preparing multi-layer lithographic printing plates according to this invention are shown in Invention Examples 1-3 below.

### Imaging and Processing

The lithographic printing plate precursors can have any useful form including, but not limited to, flat plates, printing cylinders, printing sleeves (solid or hollow cores) and printing tapes (including flexible printing webs).

Lithographic printing plate precursors can be of any size or shape (for example, square or rectangular) having the requisite one or more imageable layers disposed on a suitable substrate. Printing cylinders and sleeves are known as rotary printing members having a substrate and at least one imageable layer in cylindrical form. Hollow or solid metal cores can be used as substrates for printing sleeves.

During use, the lithographic printing plate precursors are exposed to a suitable source of infrared radiation at a wavelength of from about 600 to about 1500 nm and typically from about 700 to about 1200 nm. The lasers used for exposure are usually diode lasers, because of the reliability and low maintenance of diode laser systems, but other lasers such as gas or solid-state lasers may also be used. The combination of power, intensity and exposure time for laser imaging would be readily apparent to one skilled in the art. Presently, high performance lasers or laser diodes used in commercially available imagesetters emit infrared radiation at a wavelength of from about 800 to about 850 nm or from about 1040 to about 1120 nm.

The imaging apparatus can function solely as a platesetter or it can be incorporated directly into a lithographic printing press. In the latter case, printing may commence immediately after imaging, thereby reducing press set-up time considerably. The imaging apparatus can be configured as a flatbed recorder or as a drum recorder, with the printing plate mounted to the interior or exterior cylindrical surface of the drum. Examples of useful imaging apparatus are available as models of Kodak® Trendsetter imagesetters available from Eastman Kodak Company (Burnaby, British Columbia, Canada) that contain laser diodes that emit near infrared radiation at a wavelength of about 830 nm. Other suitable imaging sources include the Crescent 42T Platesetter that operates at a wavelength of 1064 nm and the Screen PlateRite 4300 series or 8600 series platesetter (available from Screen, Chicago, Ill.). Additional useful sources of radiation include direct imaging presses that can be used to image a precursor while it is attached to the printing plate cylinder. An example of a suitable direct imaging printing press includes the Heidelberg SM74-DI press (available from Heidelberg, Dayton, Ohio).

Imaging speeds may be in the range of from about 50 to about 1500 mJ/cm², and typically from about 75 to about 400 mJ/cm².

While laser imaging is useful in the practice of this invention, imaging can be provided by any other means that provides thermal energy in an imagewise fashion. For example, imaging can be accomplished using a thermoresistive head (thermal printing head) in what is known as “thermal printing”, as described for example in U.S. Pat. No. 5,488,025 (Martin et al.) and as used in thermal fax machines and sublimation printers. Thermal print heads are commercially available (for example, as a Fujitsu Thermal Head FTP-040 MCS001 and TDK Thermal Head F415 HH7-1089).

Direct digital imaging is generally used for imaging. The image signals are stored as a bitmap data file on a computer. Raster image processor (RIP) or other suitable means may be used to generate such files. The bitmaps are constructed to define the hue of the color as well as screen frequencies and angles.

Imaging and development of the lithographic printing plate precursor produces a lithographic printing plate that comprises a latent image of imaged (exposed) and non-imaged (non-exposed) regions.

For the imaged positive-working lithographic printing plate precursors, with or without a post-exposure baking (or pre-heat) step after imaging and before processing, the imaged elements are processed “off-press” using the fresh samples of processing solution described below according to this invention. Processing is carried out for a time sufficient to remove predominantly only the exposed regions of the outer layer and the underlying portions of underlayers (such as the inner layer), and to reveal the hydrophilic surface of the substrate, but not long enough to remove significant amounts of the non-exposed regions. The revealed hydrophilic surface repels ink while the non-exposed (or non-imaged) regions accept ink.

Conversely, if the imaged lithographic printing plate precursors are negative-working, processing according to the present invention removes predominantly only the non-exposed regions (not the exposed regions) of the imageable layer and reveals the hydrophilic surface of the substrate. Any topcoat may be removed can be removed during processing or before processing using a pre-rinse solution as is known in the art.

Thus, the regions to be removed are “soluble” or “removable” in the fresh sample of processing solution because they are removed, dissolved, or dispersed within it more readily than the regions that are to remain. The term “soluble” also means “dispersible”.

The processing solution both “develops” the imaged precursors by removing predominantly only the desired regions (development) and also provides a protective layer or coating over the entire imaged and developed surface. In this aspect, the processing solution can behave somewhat like a gum that is capable of protecting the lithographic image on the printing plate against contamination or damage (for example, from oxidation, fingerprints, dust, or scratches).

There are generally two types of “gum” solutions known in the art: (1) a “bake”, “baking”, or “pre-bake” gum usually contains one or more compounds that do not evaporate at the usual pre-bake temperatures used for making lithographic printing plates, typically an anionic or nonionic surfactant, and (2) a “finisher” gum that usually contains one or more hydrophilic polymers (such as gum Arabic, cellulosic compounds, (meth)acrylic acid polymers, and polysaccharides) that are useful for providing a protective overcoat on a printing plate. The fresh samples of processing solution used in the invention could be generally considered a “pre-bake” gum.

By using the fresh sample of processing solution described herein, the conventional aqueous alkaline developer compositions containing silicates or metasilicates, or various organic solvents, are avoided. Moreover, one advantage of this invention is that once the processing solution is used in this manner, no separate rinsing step is necessary before using the resulting lithographic printing plate for printing. However, before printing, any excess processing solution may be removed from the lithographic printing plate by wiping or use of a squeegee or a pair of nip rollers in an apparatus, followed by optional drying using any suitable drying means. Each processing solution sample is usually drained for disposal. A fresh sample of the processing solution is used for each processed lithographic printing plate precursor. This processing solution sample is not reused, recycled, replenished, or regenerated as is common in the art.

The fresh processing solution sample may be provided in diluted or concentrated form. Moreover, in processing multiple printing plate precursors, which can be the same or different, the fresh samples of processing solution can be the same or different, and thus they can be chosen for and applied in a processing apparatus upon an appropriate signal that identifies a specific type of imaged precursor to be processed. The amounts of components described below refer to amounts in the diluted processing solution samples that are the most likely form for use in the practice of the invention. However, it is to be understood that the present invention includes the use of concentrated processing solution samples and the amounts of various components (such as the anionic surfactants) would be correspondingly increased.

Each fresh sample of processing solution is used at from about 50 to about 500 ml/m² of imaged precursor, or typically from about 100 to about 300 ml/m² of imaged precursor.

The fresh processing solution samples used in the practice of this invention are aqueous solutions that generally have a pH greater than 6 and up to about 11, and typically from about 6.5 to about 11, or from about 7 to about 10.5, as adjusted using a suitable amount of an acid or base. The viscosity of the processing solution samples can be adjusted to a value of from about 1.7 to about 5 cP by adding a suitable amount of a viscosity-increasing compound such as a poly(vinyl alcohol) or poly(ethylene oxide).

Various components can be present in the sample of processing solution to provide the development and gumming functions, except for those components specifically excluded above.

For example, some of the fresh samples have as an essential component, one or more anionic surfactants, although optional components (described below) can be present if desired. Useful anionic surfactants include those with carboxylic acid, sulfonic acid, or phosphonic acid groups (or salts thereof). Anionic surfactants having sulfonic acid (or salts thereof) groups are particularly useful. For example, such anionic surfactants can include aliphates, abietates, hydroxyalkanesulfonates, alkanesulfonates, dialkylsulfosuccinates, alkyldiphenyloxide disulfonates, straight-chain alkylbenzenesulfonates, branched alkylbenzenesulfonates, alkylnaphthalenesulfonates, alkylphenoxypolyoxy-ethylenepropylsulfonates, salts of polyoxyethylene alkylsulfonophenyl ethers, sodium N-methyl-N-oleyltaurates, monoamide disodium N-alkylsulfosuccinates, petroleum sulfonates, sulfated castor oil, sulfated tallow oil, salts of sulfuric esters of aliphatic alkylester, salts of alkylsulfuric esters, sulfuric esters of polyoxy-ethylene alkylethers, salts of sulfuric esters of aliphatic monoglucerides, salts of sulfuric esters of polyoxyethylenealkylphenylethers, salts of sulfuric esters of polyoxyethylenestyrylphenylethers, salts of alkylphosphoric esters, salts of phosphoric esters of polyoxyethylenealkylethers, salts of phosphoric esters of polyoxyethylenealkylphenylethers, partially saponified compounds of styrene-maleic anhydride copolymers, partially saponified compounds of olefin-maleic anhydride copolymers, and naphthalenesulfonateformalin condensates. Alkyldiphenyloxide disulfonates (such as sodium dodecyl phenoxy benzene disulfonates), alkylated naphthalene sulfonic acids, sulfonated alkyl diphenyl oxides, and methylene dinaphthalene sulfonic acids) are particularly useful as the primary anionic surfactant. Such surfactants can be obtained from various suppliers as described in McCutcheon's Emulsifiers & Detergents, 2007 Edition.

Particular examples of such anionic surfactants include but are not limited to, sodium dodecylphenoxyoxybenzene disulfonate, the sodium salt of alkylated naphthalenesulfonate, disodium methylene-dinaphthalene disulfonate, sodium dodecylbenzenesulfonate, sulfonated alkyl-diphenyloxide, ammonium or potassium perfluoroalkylsulfonate and sodium dioctylsulfosuccinate.

The one or more anionic surfactants are generally present in each fresh sample of processing solution an amount of at least 1 weight %, and typically from about 5 weight % or from about 8 weight % and up to about 45 weight %, or up to about 30 weight % (% solids). In some embodiments, the one or more anionic surfactants may be present in an amount of from about 8 to about 20 weight %. The amounts of anionic surfactants can vary from one fresh sample to another fresh sample.

Two or more anionic surfactants (“first”, “second”, etc.) can be used in combination. In such mixtures, a first anionic surfactant, such as an alkyldiphenyloxide disulfonate, can be present generally in an amount of at least 1 weight % and typically from about 5 to about 20 weight %. A second surfactant can be present (same or different from the first anionic surfactant) in a total amount of at least 1 weight %, and typically from about 3 to about 20 weight %. Second or additional anionic surfactants can be selected from the substituted aromatic alkali alkyl sulfonates and aliphatic alkali sulfates. One particular combination of anionic surfactants includes one or more alkyldiphenyloxide disulfonates and one or more aromatic alkali alkyl sulfonates (such as an alkali alkyl naphthalene sulfonate).

The fresh processing solution samples useful in this invention may optionally include nonionic surfactants as described in [0029] or hydrophilic polymers described in [0024] of EP 1,751,625 (noted above), incorporated herein by reference. Particularly useful nonionic surfactants include Mazol® PG031-K (a triglycerol monooleate, Tween® 80 (a sorbitan derivative), Pluronic® L62LF (a block copolymer of propylene oxide and ethylene oxide), and Zonyl® FSN (a fluorocarbon), and a nonionic surfactant for successfully coating the processing solution onto the printing plate surface, such as a nonionic polyglycol. These nonionic surfactants can be present in an amount of up to 10 weight %, but at usually less than 2 weight % (% solids). The amounts of nonionic surfactants can be the same or different in the individual fresh samples.

Other optional components of the fresh processing solution samples include inorganic salts (such as those described in [0032] of U.S. Patent Application Publication 2005/0266349, noted above), wetting agents (such as a glycol), metal chelating agents, antiseptic agents, organic amines, anti-foaming agents, ink receptivity agents (such as those described in [0038] of US '349), and viscosity increasing agents as noted above. The amounts of such components are known in the art. Other useful addenda include but not limited to, phosphonic acids or polycarboxylic acids, or salts thereof that are different than the anionic surfactants described above. Such polyacids can be present in an amount of at least 0.001 weight % and typically from about 0.001 to about 10 weight % (% solids), and can include but are not limited to, polyaminopolycarboxylic acids, aminopolycarboxylic acids, or salts thereof, [such as salts of ethylenediaminetetraacetic acid (EDTA, sodium salt)], organic phosphonic acids and salts thereof, and phosphonoalkanetricarboxylic acids and salts thereof.

The fresh samples of processing solution can be applied to the imaged precursor by rubbing, spraying, jetting, dipping, immersing, slot die coating (see for example, FIGS. 1 and 2 of U.S. Pat. No. 6,478,483 of Maruyama et al.) or reverse roll coating (as described in FIG. 4 of U.S. Pat. No. 5,887,214 of Kurui et al.), or wiping the outer layer with the processing solution sample or contacting it with a roller, impregnated pad, or applicator containing the processing solution sample. For example, the imaged element can be brushed with the fresh sample of processing solution, or it can be poured onto or applied by spraying the imaged surface with sufficient force to remove the exposed regions using a spray nozzle system or shower piper as described for example in [0124] of EP 1,788,431A2 (noted above) and U.S. Pat. No. 6,992,688 (Shimazu et al.). Still again, the imaged element can be immersed in the sample of processing solution and rubbed by hand or with an apparatus.

The fresh sample of processing solution can also be applied in a processing unit (or station) in a suitable apparatus that has at least one roller for rubbing or brushing the precursor while the processing solution is applied. By using such a processing unit, the desired regions of the imaged layer may be removed from the substrate more completely and quickly. Residual processing solution may be removed (for example, using a squeegee or nip rollers) or left on the resulting printing plate without any rinsing step. Excess processing solution sample can be collected or drained immediately for disposal. As noted above, the used processing solution is not reused or recycled. So, the processing apparatus can be modified to use only fresh samples of the processing solution for individual imaged precursors, for example, as the modified Unigraph Compact Microtec 60 desktop plate processor used in the Invention Examples below.

Following processing, the resulting lithographic printing plate can be used for printing without any need for a separate rinsing step using water.

The resulting lithographic printing plates can also be baked in a postbake operation that can be carried out to increase run length. Baking can be carried out, for example, in a suitable oven at a temperature of less than 300° C. and typically at less than 250° C. for from about 2 to about 10 minutes. More typically, the baking is done very quickly at a temperature of from about 160° C. to about 220° C. (for example, at 190° C.) for up to five minutes (for example, up to two minutes). In some embodiments, the lithographic printing plate is postbaked at from about 160 to about 220° C. for up to two minutes

Alternatively, the lithographic printing plate can be baked or cured by overall exposure to IR radiation at a wavelength of from about 800 to about 850 nm. This exposure creates conditions that enable very controllable baking effects with minimal distortion. For example, the lithographic printing plate can be passed through a commercial QuickBake 1250 oven (available from Eastman Kodak Company) at 4 feet (1.3 m) per minute at the 45% power setting of an infrared lamp to achieve a similar baking result from heating the plate in an oven at 200° C. for 2 minutes.

A lithographic ink, fountain solution, or both, can be applied to the printing surface of the processed lithographic printing plate for printing. The non-removed regions of the outermost layer take up ink and the hydrophilic surface of the substrate revealed by the imaging and processing takes up fountain solution. The ink is then transferred to a suitable receiving material (such as cloth, paper, metal, glass, or plastic) to provide one or more impressions of the image thereon. If desired, an intermediate “blanket” roller can be used to transfer the ink from the lithographic printing plate to the receiving material. The lithographic printing plates can be cleaned between impressions, if desired, using conventional cleaning means and chemicals.

The following examples are presented to illustrate the practice of this invention but are not intended to be limiting in any manner.

### EXAMPLES

Unless otherwise indicated, the following materials were obtained from a commercial source such as Aldrich Chemical Company (Milwaukee, Wis.).

Byk® 307 is a polyethoxylated dimethylpolysiloxane copolymer that is available from Byk Chemie (Wallingford, Conn.) in a 25 wt. % xylene/-methoxypropyl acetate solution.

Byk® 331 is a polyether modified dimethylpolysiloxane copolymer that is available from Byk Chemie.

BLO represents γ-butyrolactone.

Copolymer A represents a copolymer having recurring units derived from N-phenyl maleimide, methacrylamide, and methacrylic acid (41.5:37.5:21 mol %) using conventional conditions and procedures.

Copolymer B represents a copolymer having recurring units derived from N-phenyl maleimide, methacrylamide, methacrylic acid, acrylonitrile, styrene, and ethylene glycol methacrylate phosphate (12:33:12:34:6:3 mol %) using conventional conditions and procedures.

Copolymer C represents a copolymer derived from methyl methacrylate, benzyl methacrylate, and Intermediate A (described below) (24:24:52% by weight) using conventional conditions and procedures.

Copolymer D represents a copolymer derived from carboxyphenyl methacrylamide, acrylonitrile, methacrylamide, and N-phenyl maleimide (37/48/10/5 wt.%) using conventional conditions and procedures.

Copolymer E represents a 24 wt. % dispersion (in 76:24 n-propanol/water) of a Copolymer 7 described in U.S. Pat. No. 7,261,998 (Hayashi et al.) incorporated herein by reference.

Copolymer F was prepared as follows:

A 20 g solution of poly (ethylene glycol) methyl ether methacrylate [PEGMA-50% solution in water (available from Aldrich)] dissolved in a mixture of 74.8 g of deionized water and 241.4 g of n-propanol, was charged into a 1000 ml 4-neck flask, which was heated slowly to slight reflux (76° C.) under nitrogen atmosphere. A pre-mixture of 15.0 g of styrene, 70 g of acrylonitrile, 5 g of acrylic acid, and 0.7 g of azoisobutyronitrile (Vazo-64, from Dupont de Numours Co) was added in two hours period. Six hours later, another 0.35 g of azoisobutyronitrile (Vazo-64) was added. The reaction temperature was raised to 80° C. Three hours later, 0.35 g of Vazo-64 was added. After 19 hours, the conversion to graft copolymer was >92% based on determination of percent non-volatiles. The weight ratio of PEGMA/styrene/acrylonitrile/acrylic acid was 10:15:70:5 and n-propanol/water ratio is 76:24 and the acid number of this graft copolymer was 36.4 (actual) versus 38.9 (Theo).

Crystal Violet is a violet dye C.I. 42555; CAS 548-62-9 [(p-(CH₃)₂NC₆H₄)₃C⁺Cl⁻] that is available from Aldrich (Milwaukee, Wis.).

D11 represents ethanaminium, N-[4-[[4-(diethylamino)phenyl][4-(ethylamino)-1-naphthalenyl]methylene]-2,5-cyclohexadien-1-ylidene]-N-ethyl-, salt with 5-benzoyl-4-hydroxy-2-methoxybenzenesulfonic acid (1:1) as supplied by PCAS (Longjumeau, France).

DEK represents diethyl ketone.

Dow Additive 19 is a silicone additive that is available from Dow Corning (Midland, Mich.).

Ethyl violet is assigned C.I. 42600 (CAS 2390-59-2, λₘₐₓ=596 nm) and has the formula of p-(CH₃CH₂)₂NC₆H₄)₃C⁺Cl⁻.

FluorN2900 is a fluorosurfactant that was obtained from Cytonix Corporation (Beltsville, Md.).

Gum N1 (also N1 finisher gum) is a prebake gum consisting of MX1591 (980 parts) and EDTA tetrasodium salt (20 parts) and had a pH of 9.4.

IB05 bis(4-t-butylphenyl) iodonium tetraphenylborate.

Intermediate A was prepared by charging dimethylacetamide (246.6 g), HEMA, 2-hydroxy ethyl methacrylate (65 g), and dibutyl tin dilaurate (0.42 g) into a 500 ml 4-neck ground glass flask, equipped with a heating mantle, temperature controller, mechanical stirrer, condenser, pressure equalized addition funnel and nitrogen inlet. The reaction mixture was heated to 60° C. under nitrogen atmosphere. Then, p-toluene sulfonyl isocyanate (98.6 g) was added at 60° C. over a period of one hour. The reaction was completed in six hours as determined by the disappearance of isocyanate infrared absorption band at 2275cm⁻¹. At the end of the reaction, methanol (5 g) was added. The resulting intermediate had an acid number of 163.6 and was used to prepare Copolymer C.

IPA represents n-isopropyl alcohol.

IR Dye A is Kayasorb PS210CnE, an infrared absorbing dye as supplied by Nippon Kayaku Co, Ltd., Tokyo, Japan.

IRT is an IR dye that was obtained from Showa Denko (Japan) and having the structure:

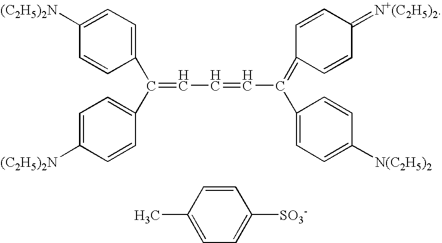

Masurf FS-1520: a fluoroaliphatic betaine fluorosurfactant that was obtained from Mason Chemical Company (Arlington Heights, Ill.).

MeOH represents methanol.

MX1591 is a prebake gum solution that is available from Eastman Kodak (Rochester, N.Y.).

NK Ester A-DPH is a dipentaerythritol hexaacrylate that was obtained from Kowa American (New York, N.Y.).

NPB 269 is a copolymer prepared as follows:

AIBN [2,2′-azobis(iso-butyronitrile), Vazo-64, 0.8 g], methyl methacrylate (10 g), acrylonitrile (10 g), N-vinyl carbazole (4 g, from Polymer Dajac), methacrylic acid (12 g), PEGMA (8 g), and DMAC (160 g) were placed in a 1000-ml 3-necked flask, equipped with magnetic stirring, temperature controller, and N₂ inlet. The reaction mixture was heated to 75° C. and stirred under N₂ protection overnight (about 16 hours). The % N.V. was measured with about 20%. To above reaction mixture (after nitrogen protection was removed and temperature was reduced to 55° C.), potassium hydroxide (3.7 g) in water (20 g) was slowly added and a viscous liquid was formed. After stirring the mixture for 20 minutes, allyl bromide (8.0 g) was added and the mixture was stirred at 55° C. for 3 hours. Concentrated (36%) hydrochloric acid (7 g) in DMAC (25 g) was added to the flask and the reaction mixture was stirred for another 3 hours. The resulting reaction mixture was then slowly dropped into a mixture of 6 liters of ice water with 10 g of concentrated hydrochloric acid while stirring. The resulting precipitate was filtered and a fine white powder was obtained after filtration. The powder was dried at room temperature overnight and then at 50° C. for 3 hours to obtain 39 g of polymer solid.

NPB-270 is a copolymer prepared as follows:

AIBN [2,2′-azobis(iso-butyronitrile), Vazo-64, 0.8 g], methyl methacrylate (5 g), acrylonitrile (15 g), N-vinyl carbazole (4 g, from Polymer Dajac), methacrylic acid (12 g), PEGMA (8 g), and DMAC (160 g) were placed in a 1000-ml 3-necked flask, equipped with magnetic stirring, temperature controller, and N₂ inlet. The reaction mixture was heated to 75° C. and stirred under N₂ protection overnight (about 16 hours). The % N.V. was measured with about 20%. To above reaction mixture (after nitrogen protection was removed and temperature was reduced to 55° C.), potassium hydroxide (3.7 g) in water (20 g) was slowly added and a viscous liquid was formed. After stirring the mixture for 20 minutes, allyl bromide (8.0 g) was added and the mixture was stirred at 55° C. for 3 hours. Concentrated (36%) hydrochloric acid (7 g) in DMAC (25 g) was added to the flask and the reaction mixture was stirred for another 3 hours. The resulting reaction mixture was then slowly dropped into a mixture of 6 liters of ice water with 10 g of concentrated hydrochloric acid while stirring. The resulting precipitate was filtered and a fine white powder was obtained after filtration. The powder was dried at room temperature overnight and then at 50° C. for 3 hours to obtain 36 g of polymer solid.

PGME represents 1-methoxypropan-2-ol (also known as Dowanol® PM).

PGMEA represents poly(ethylene glycol) methyl ether methacrylate.

Phosmer PE is an ethylene glycol methacrylate phosphate with 4-5 ethoxy groups that was obtained from Uni-Chemical Co. Ltd. (Japan).

Pigment 951 is a 27% solids dispersion of 7.7 parts of a polyvinyl acetal derived from poly(vinyl alcohol) acetalized with acetaldehyde, butyraldehyde, and 4-formylbenzoic acid, 76.9 parts of Irgalith Blue GLVO (Cu-phthalocyanine C.I. Pigment Blue 15:4), and 15.4 parts of Disperbyk® 167 dispersant (Byk Chemie) in 1-methoxy-2-propanol.

PVA 405 is a poly(vinyl alcohol) that was obtained from Kuraray America Inc. (New York, N.Y.) having a hydrolysis degree of 80-83%.

RX-04 is a copolymer of styrene and maleic anhydride that is available form Gifu Shellac, Japan.

S0507 is an IR dye that was obtained from FEW Chemicals GmbH (Germany) and has the following structure:

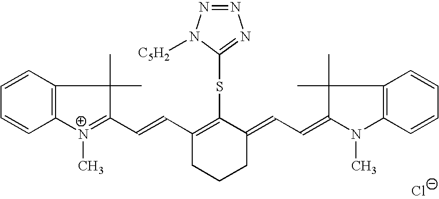

Sipomer PAM-100 is an ethylene glycol methacrylate phosphate having 4-5 ethylene glycol units, that was obtained from Rhodia (Cranbury, N.J.).

SR-399 is dipentaerythritol pentaacrylate that was obtained from Sartomer Company, Inc. (Exton, Pa.).

SR-499 is ethoxylated (6) trimethylolpropane triacrylate that was also obtained from Sartomer Company, Inc.

Substrate A is a 0.3 mm gauge aluminum sheet that had been electrograined, anodized, and treated with poly(vinyl phosphonic acid).

TMSPMA is trimethoxysilylpropyl methacrylate.

A modified processor was used to developed imaged lithographic printing plate precursors in the practice of this invention as follows:

A Unigraph Compact Microtec 60 desktop plate processor (serial number 8461/TX, Unigraph Equipment Ltd, Thetford, UK) was modified such that processing solution (for example, Gum N1) was pumped from a container, through a pump (model AC-56-Md, March Manufacturing Inc., Glenview, Ill.) and valve, and into a 6 inch ( 15.2 cm) wide slot applicator. A bead of the processing solution was then applied onto the imaged surface of each incoming imaged element. With this arrangement, a fresh sample of the processing solution (Gum N1) could be applied to individual imaged elements. After application, the processing solution spread over the entire element surface. Excess and used processing solution was then drained through an exit in the processor tank floor for disposal. The processor had the following measurements:

Brush speed=40 rpm

Transport speed=1.0 ft/min. (30.5 cm/min.)

Nip to nip time=60 seconds

Nip to plush roller length=6 inches (15.2 cm)

Nip to nip length=12 inches (30.5 cm).

Inner Layer Formulation 1:

| | |
|---|---|
| Copolymer A | 0.712 g |
| Copolymer D | 0.378 g |
| PS210CnE | 0.150 g |
| D11 (1% solution in solvent noted below) | 0.630 g |
| Byk ® 307 (10% solution in DEK) | 0.126 g |
| Solvent: (MEK/PGME/BLO/water 50/30/10/10 wt %) | 16.00 g |

Outer Layer Formulation 1:

| | |
|---|---|
| Copolymer C | 1.238 g |
| Ethyl violet (1% solution in DEK) | 0.300 g |
| Byk ® 307 (10% solution in DEK) | 0.088 g |
| Solvent: (DEK/PGMEA 92/8 wt %) | 23.37 g |

Inner Layer Formulation 2:

| | |
|---|---|
| Copolymer B | 6.474 g |
| PS210CnE | 0.936 g |
| D11 | 0.078 g |
| Dow Additive 19 | 0.234 g |
| Byk ® 307 (10% solution in DEK) | 0.780 g |
| Solvent: (MEK/PGME/BLO/water 50/30/10/10 wt %) | 111.5 g |

Outer Layer Formulation 2:

| | |
|---|---|
| RX-04 | 1.238 g |
| Ethyl violet (1% solution in DEK) | 0.375 g |
| Byk ® 307 (10% solution in DEK) | 0.252 g |
| Solvent: (DEK/PGMEA 92/8 wt %) | 76.2 g |

Inner Layer Formulation 3:

| | |
|---|---|
| Copolymer B | 11.07 g |
| PS210CnE | 1.590 g |
| D11 | 0.100 g |
| Dow Additive 19 | 0.430 g |
| Byk ® 331 (10% solution in DEK) | 0.03 g |
| Solvent (MEK/PGME/BLO/water 50/30/10/10 wt. %) | 236.8 g |

Outer Layer Formulation 3:

| | |
|---|---|
| RX-04 | 5.440 g |
| Crystal violet | 0.550 g |
| Dow Additive 19 | 0.020 g |
| Solvent (DEK/PGMEA 92/8 wt. %) | 194.5 g |

Photosensitive Layer Composition 1:

| | |
|---|---|
| NPB-270 (10% in MEK/PGME/BLO/water 5/2/1/1) | 7.70 g |
| SR-499 | 0.200 g |
| SR-399 | 0.400 g |
| NK ester DPH-A | 0.400 g |
| Phosmer PE | 0.100 g |
| IB-05 | 0.150 g |
| SO507 IR Dye | 0.050 g |
| Pigment 951 | 0.500 g |
| FluorN 2900 (5% in PGME) | 0.400 g |
| Solvent (MEK/PGME/BLO/MeOH/water 4/3/1/1/1) | 10.0 g |

Topcoat Composition:

| | |
|---|---|
| PVA 405 | 4.00 g |
| Masurf FS-1520 | 0.02 g |
| Solvent: (IPA/water 4/96) | 96.0 g |

Photosensitive Layer Composition 2:

| | |
|---|---|
| Copolymer F (15% in IPA/water 74/26) | 2.60 g |
| NPB-270 (10% in MEK/PGME/BLO/water 5/2/1/1) | 3.90 g |
| SR-499 | 0.200 g |
| SR-399 | 0.400 g |
| NK ester DPH-A | 0.400 g |
| Phosmer PE | 0.100 g |
| IB-05 | 0.150 g |
| SO507 IR Dye | 0.050 g |
| Pigment 951 | 0.500 g |
| FluorN 2900 (5% in PGME) | 0.400 g |
| Solvent (MEK/PGME/BLO/MeOH/water 5/3/1/1/1) | 11.0 g |

Photosensitive Layer Composition 3:

| | |
|---|---|
| NPB-269 | 2.343 g |
| TMSPMA | 0.187 g |
| NK ester DPH-A | 2.999 g |
| Copolymer E (23.5% in IPA/water 74/26) | 9.970 g |
| IB-05 | 0.656 g |
| PAM-100 | 0.187 g |
| IRT | 0.281 g |
| Byk ® 307 (10% PGME) | 0.937 g |
| Pigment 951 | 2.811 g |
| Solvent (PGME/MEK/water 65/35/5) | 129.6 g |

### Lithographic Printing Plate Precursor 1:

A two-layer, IR-sensitive, positive-working lithographic printing plate precursor was prepared by applying Inner Layer Formulation 1 to Substrate A using a 0.012 inch (0.030 cm) wire-wound bar and dried for 35 seconds at 120° C. to provide a dry coating weight of approximately 1.5 g/m². Outer Layer Formulation 1 was then applied over the dried inner layer using a 0.006 inch (0.030 cm) wire-wound bar and dried for 35 seconds at 120° C. to provide a dry coat weight of approximately 0.5 g/m².

### Lithographic Printing Plate Precursor 2:

A two-layer, IR-sensitive, positive-working lithographic printing plate precursor was prepared by applying Inner Layer Formulation 2 to Substrate A using a 0.012 inch (0.030 cm) wire-wound bar and dried for 35 seconds at 120° C. to provide a dry coating weight of approximately 1.35 g/m². Outer Layer Formulation 2 was then applied to the dried inner layer using a 0.006 inch (0.030 cm) wire-wound bar and dried for 30 seconds at 120° C. to provide a dry coat weight of approximately 0.45 g/m².

### Lithographic Printing Plate Precursor 3:

A two-layer, IR-sensitive, positive-working lithographic printing plate precursor was produced according to the following method:

Inner Layer Formulation 3 was applied to Substrate A using a laboratory hopper coater. The application rate was adjusted to provide a dry coat weight of 1.5 g/m². The coating was dried for 60 seconds at 70° C. Outer Layer Formulation 3 was applied with a hopper coater to provide a dry coat weight of 0.60 g/m² and dried at 65° C. for 60 seconds. Imageable Element 3 was subsequently dried again at 120° C. for 30 seconds.

### Lithographic Printing Plate Precursor 4:

A two-layer, IR-sensitive, negative-working lithographic printing plate precursor was produced according to the following method:

Photosensitive Layer Composition 1 was applied to Substrate A using a 0.006 inch (0.015 cm) wire-wound bar to provide a dry coat weight of 1.1 g/m². The coating was dried for 60 seconds at 120° C. The Topcoat Composition was similarly applied and dried to provide a dry coat weight of 0.40 g/m².

### Lithographic Printing Plate Precursor 5:

A two-layer, IR-sensitive, negative-working lithographic printing plate precursor was produced according to the following method:

Photosensitive Layer Composition 2 was applied to Substrate A using a 0.006 inch (0.015 cm) wire-wound bar and dried for 60 second at 120° C. to provide a dry coating weight of approximately 1.1 g/m². The Topcoat Composition was similarly applied and dried to provide a dry coat weight of approximately 0.4 g/m².

### Lithographic Printing Plate Precursor 6:

A single-layer, IR-sensitive, negative-working lithographic printing plate precursor was produced according to the following method:

Photosensitive Layer Composition 3 was applied to Substrate A using a laboratory hopper coater and dried for 90 second at 99° C. to provide a dry coating weight of approximately 1.3 g/m². No topcoat was applied.

### Invention Examples 1 and 2

Lithographic Printing Plate Precursors 1 and 2 were imaged using a Screen PTR₄₃₀₀ platesetter. Internal test pattern C1 was imaged at exposure powers of 45 to 100% in increments of 5% using a drum speed of 1000 rpm. The imaged precursors were processed using the modified Microtec 60 processor containing a fresh sample of Gum N1 as the processing solution that was applied at about 50 ml/ft² (540 ml/m²) for both development and protective gumming. Gum N1 was maintained at a temperature of 30° C. and processing was carried out at a speed of 1 ft/min. (0.3 m/min.). The used and excess Gum N1 was drained without reuse for disposal. The precursors were evaluated for development time, the exposure energy required to give a clean image, and the exposure energy required to give a clean image, and the exposure energy required to give the best image reproduction. The results are presented in the following TABLE I. The results indicate that both Lithographic Printing Plate Precursors 1 and 2 were easily processed to provide desired high-resolution images.

TABLE I

| Invention | | Exposure | Exposure | |
|---|---|---|---|---|
| Example | Precursor | (Cleanout) | (Best reproduction) | Comments |
| 1 | 1 | 75% power | 85% power | Good image, high |
| | | | | resolution, easy to develop |
| 2 | 2 | 75% power | 85% power | Good image, high |
| | | | | resolution, easy to develop |

### Invention Example 3

Lithographic printing plate precursor 3 was imaged with a Kodak® Trendsetter 800II Quantum platesetter using internal test patterns ‘plot 0’ and ‘plot 12’. Exposures were performed at 120 mJ/cm² at a head power of 9 watts. The imaged precursor was processed using the modified adapted Microtec 60 processor containing a fresh sample of Gum N1 as the processing solution at about 50 ml/ft² (540 ml/m²) to provide both development and protective gumming. Gum N1 was maintained at a temperature of 30° C. and the imaged precursor were processed at a conveyor speed of 1 ft/min. (0.3 m/min.). Used and excess Gum N1 was drained without reuse for disposal.

The resulting lithographic printing plate was mounted directly on an A.B. Dick 9870 Duplicator Press (A.B. Dick, Niles, Ill.) that was charged with Van Son Rubber Base black Ink (Van Son Ink, Mineola, N.Y.). An aqueous fountain solution contained about 23.5 ml/liter (3 oz per gallon) Varn Litho Etch142W (Varn International, Addison, Ill.), and about 23.5 ml/liter (3 oz per gallon) Varn PAR (alcohol substitute) in water. Before the printing press was started, a small amount of fountain solution in a non-abrasive cloth was applied to the printing plate. The printing press was then started and the damping system engaged to further wet the plate with fountain solution. After a few revolutions, the inking system was engaged and 200 copies were printed. The printed sheets were assessed for number of sheets to print a clean background, number of sheets to get to full ink density, and general image quality. The results are shown below in TABLE II.

TABLE III

| Number of | | | |
|---|---|---|---|
| Sheets to | Number of | | |
| Print Clean | Sheets to | Print | |
| Background | Full Ink Density | Quality | Comments |
| <5 | 25 | Very good | Good, clean printed copies |
| | | | were obtained |

### Invention Examples 4 and 5

Lithographic printing plate precursors 4 and 5 were imaged using a Kodak® Trendsetter 800Quantum platesetter and internal test pattern ‘plot 50’ and ‘plot 12’. The precursors were exposed at energies of 10 to 100 mJ/cm² at head powers of 1 to 10 watts and a fixed drum speed of 250 rpm. The imaged precursors were processed using the modified Microtec 60 processor containing a fresh sample of Gum N1 as the processing solution at about 50 ml/ft² (540 ml/m²) for both development and protective gumming. The Gum N1 was maintained at a temperature of 30° C. while the precursors were processed at a conveyor speed of 1 ft/min. (0.3 m/min.). Used and excess Gum N1 was drained without reuse for disposal. The resulting lithographic printing plates were evaluated for the minimum exposure energy (mJ/cm²) required to provide a solid image and exposure energy (mJ/cm²) required to give best image reproduction. The results are shown in the following TABLE III.

TABLE III

| | | Minimum | Exposure for | |
|---|---|---|---|---|
| Invention | | Exposure | Best | |
| Example | Precursor | Requirement | Reproduction | Comments |
| 4 | 4 | 50 | 90 | |
| 5 | 5 | 40 | 90 | |

### Invention Example 6

Lithographic printing plate precursor 6 was imaged using a Kodak® Trendsetter 800II Quantum platesetter using internal test patterns ‘plot 12’ and ‘plot 22’ for exposure at energies of 40 to 180 mJ/cm² at a head power of 5.5 watts. The imaged precursor was processed with the modified Microtec 60 processor containing a fresh sample of Gum N1 as the processing solution at about 50 ml/ft² (540 ml/m²) for both development and protective gumming. The Gum N1 was maintained at a temperature of 30° C. The imaged precursors were processed at a conveyor speed of 1 ft/min. (0.3 m/min.) and the used and excess Gum N1 was drained without reuse for disposal. The resulting lithographic printing plate was evaluated for the minimum exposure energy (mJ/cm²) required to give a solid image and the exposure energy (mJ/cm²) required to give best image reproduction. The results are shown below in TABLE IV.

TABLE IV

| | | Minimum | | |
|---|---|---|---|---|
| Invention | | Exposure | Exposure for Best | |
| Example | Precursor | Requirement | Reproduction | Comments |
| 6 | 6 | 110 | 120 | |

The lithographic printing plate was then mounted directly on an A.B. Dick 9870 Duplicator Press (A.B. Dick, Niles, Ill.) that was charged with Van Son Rubber Base black Ink (Van Son Ink, Mineola, N.Y.). An aqueous fountain solution contained about 23.5 ml/liter (3 oz per gallon) Varn Litho Etch142W (Varn International, Addison, Ill., USA), and about 23.5 ml/liter (3 oz per gallon) Varn PAR (alcohol substitute) in water. Before the printing press was started, a small amount of fountain solution in a non-abrasive cloth was applied to the printing plate. The printing press was then started and the damping system engaged to further wet the plate with fountain solution. After a few revolutions, the inking system was engaged and 200 copies were printed. The printed sheets were assessed for number of sheets to print a clean background, number of sheets to get to full ink density, and general image quality.

| # Sheets to Print | # Sheets to Full | Print | |
|---|---|---|---|
| Clean Background | Ink Density | quality | Comments |
| <5 | 40 | Very good | Good, clean printing |
| | | | copies were obtained |

The invention has been described in detail with particular reference to certain preferred embodiments thereof, but it will be understood that variations and modifications can be effected within the spirit and scope of the invention.

1. A method of making an image comprising:
A) imagewise exposing a lithographic printing plate precursor comprising a substrate that has a hydrophilic surface using infrared radiation to provide both exposed and non-exposed regions in said imaged precursor,
said lithographic printing plate precursor further comprising an infrared radiation absorbing compound, and
B) applying a fresh sample of a processing solution having a pH of from about 6 to about 11 to said imaged precursor both: (1) to remove predominantly only either said exposed regions or said non-exposed regions, and (2) to provide a protective coating over all of the exposed and non-exposed regions of the resulting imaged lithographic printing plate, and said fresh sample of processing solution is not reused.

2. The method of claim 1 further comprising:
C) removing excess processing solution from said imaged lithographic printing plate, and optionally drying it, before it is used for lithographic printing.

3. The method of claim 1 wherein said processing solution comprises at least 1 weight % of an anionic surfactant.

4. The method of claim 1 wherein said processing solution is essentially free of silicates, metasilicates, and organic solvents.

5. The method of claim 1 wherein said fresh sample of processing solution is used at from about 50 to about 500 ml/m² of imaged precursor.

6. The method of claim 1 wherein said lithographic printing plate precursor is a positive-working lithographic printing plate precursor.

7. The method of claim 6 wherein said positive-working lithographic printing plate precursor comprises a substrate having thereon in order:
an inner layer comprising a first polymeric binder, and
an ink receptive outer layer comprising a second polymeric binder that is different than said first polymeric binder.

8. The method of claim 1 wherein said processing solution consists essentially of from about 1 to about 45 weight % of one or more anionic surfactants.

9. The method of claim 1 wherein said processing solution includes at least 0.001 weight % of an organic phosphonic acid or polycarboxylic acid, or a salt of either acid that is different than said one or more anionic surfactants.

10. The method of claim 1 wherein said processing solution includes from about 0.001 to about 10 weight % of a salt of a polycarboxylic acid.

11. The method of claim 1 wherein said processing solution comprises at least one anionic surfactant that has a sulfonic acid group or salt thereof that is present in an amount of from about 5 to about 45 weight %.

12. The method of claim 11 wherein said processing solution comprises two or more anionic surfactants, at least one of which is an alkyldiphenyloxide disulfonate that is present in an amount of from about 8 to about 30 weight %.

13. The method of claim 12 wherein said processing solution comprises two or more different anionic surfactants, at least one of which is an alkali alkyl naphthalene sulfonate that is present in an amount of from about 8 to about 20 weight %.

14. The method of claim 7 wherein said infrared radiation absorbing compound is an IR absorbing dye that is present predominantly in said inner layer in an amount of at least 3 weight %,
said second polymeric binder is selected from one or more of the following groups of polymer materials:
Class a): novolak resins, resole resins, branched or unbranched polyhydroxystyrenes, polyvinyl acetals with pendant phenol groups, or any combination thereof,
Class b): polymers having recurring units derived from one or more monomers of group (a) that is selected from the group consisting norbornene, tetracyclododecene, and mixtures thereof, and recurring units derived from one or more monomers of group (b) that is selected from the group consisting of maleic anhydride, maleimide, N-phenyl maleimide, N-benzyl maleimide, N-cyclohexyl maleimide, and mixtures thereof,
Class c): copolymers derived from maleic anhydride and monomers of the formula CH₂═CH(C₆H₄R¹) and mixtures thereof in which R¹ is hydrogen, halogen, hydroxyl, cyano, sulfonamide, alkyl of 1 to 6 carbon atoms, alkoxyl of 1 to 6 carbon atoms, acyl of 1 to 7 carbon atoms, acyloxy of 1 to 7 carbon atoms, carboalkoxy of 1 to 7 carbon atoms, or a mixture thereof,
Class d): copolymers derived from methyl methacrylate and a carboxylic acid containing monomer or a mixture of carboxylic acid containing monomers,
Class e): polymers having an —X‘3C(=T)-NR—S(═O)₂— moiety that is attached to the polymer backbone, wherein —X— is an oxy or —NR′— group, T is O or S, R and R′ are independently hydrogen, halo, or an alkyl group having 1 to 6 carbon atoms, and
Class f): polymers having recurring units represented by the following Structure (I-F) or (II-F): 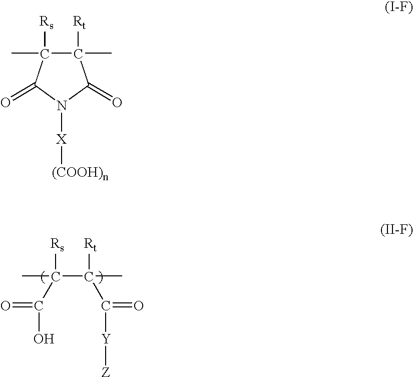
wherein n is 1 to 3, Rₛ and Rₜ are independently hydrogen or an alkyl or halo group, X is a multivalent linking group, Y is oxy or —NR— wherein R is hydrogen or an alkyl or aryl group, and Z is a monovalent organic group, and
said first polymeric binder is a (meth)acrylic resin comprising carboxy groups, poly(vinyl acetal), a maleated wood rosin, a vinyl acetate-crotonate-vinyl neodecanoate copolymer, a phenolic resin, a copolymer derived at least in part from styrene and maleic anhydride, a polymer derived at least in part from a (meth)acrylamide, a polymer derived at least in part from a (meth)acrylonitrile, a polymer derived at least in part from an N-substituted cyclic imide, a polymer derived at least in part from a (meth)acrylate having pendant hydroxy groups, a polymer having pendant cyclic urea groups, a polymer derived at least in part from an N-alkoxyalkyl methacrylamide, a polymer derived at least in part from styrene or a styrene derivative, a polymer derived at least in part from a phosphate (meth)acrylate ester, or a copolymer derived from an N-substituted cyclic imide, a (meth)acrylonitrile, a (meth)acrylamide, and (meth)acrylic acid.

15. The method of claim 1 wherein said processing solution has a pH of from about 7 to about 10.5 and comprises one or more anionic surfactants that are present in an amount of from about 5 to about 45 weight %, at least one of which has a sulfonic acid group or salt thereof.

16. The method of claim 1 wherein after step B), said lithographic printing plate is postbaked at from about 160 to about 220° C. for up to two minutes.

17. The method of claim 1 wherein said lithographic printing plate precursor is a negative-working lithographic printing plate precursor comprising a single imageable layer on said substrate, said imageable layer comprising:
a free-radically polymerizable component,
an initiator composition that provides free radical upon exposure to infrared radiation,
an infrared radiation absorbing compound, and
a polymeric binder, and optionally comprising a topcoat disposed on said imageable layer.

18. A method of making multiple lithographic printing plates comprising:
A) imagewise exposing a first lithographic printing plate precursor comprising a substrate that has a hydrophilic surface using infrared radiation to provide both exposed and non-exposed regions in said imaged precursor,
B) applying a fresh sample of a processing solution having a pH of from about 6 to about 11 to said imaged precursor both: (1) to remove predominantly only either said exposed or non-exposed regions, and (2) to provide a protective coating over all of said exposed and non-exposed regions of the resulting first imaged lithographic printing plate, and said fresh sample of processing solution is not reused, and
C′) repeating steps A and B using an additional fresh sample of the same processing solution used in step B for each of one or more additional lithographic printing plate precursors, which additional fresh samples are not reused.

19. The method of claim 18 wherein said one or more additional lithographic printing plate precursors are the same or different as said first lithographic printing plate precursor.

20. The method of claim 19 wherein said first and one or more additional lithographic printing plate precursors have essentially the same aluminum-containing substrate and layer composition(s).

21. The method of claim 19 wherein said first and one or more additional lithographic printing plate precursors are all positive-working multi-layer lithographic printing plate precursors, each of which comprises an aluminum-containing substrate having thereon, in order:
an inner layer comprising a first polymeric binder and an IR dye, and
an ink receptive outer layer comprising a second polymeric binder that is different than said first polymeric binder.

22. The method of claim 19 wherein said first and one or more additional lithographic printing plate precursors are negative-working lithographic printing plates, each of which comprises an aluminum-containing substrate having thereon an imageable layer comprising:
a free-radically polymerizable component,
an initiator composition that provides free radical upon exposure to infrared radiation,
an infrared radiation absorbing compound, and
a polymeric binder, and
optionally comprising a topcoat disposed on said imageable layer.

23. A method of making multiple lithographic printing plates comprising:
A) imagewise exposing a one or more lithographic printing plate precursors each comprising a substrate that has a hydrophilic surface using infrared radiation to provide both exposed and non-exposed regions in said one or more imaged precursors,
B) applying to each imaged precursor, a fresh sample of the same processing solution having a pH of from about 6 to about 11 to said imaged precursor both: (1) to remove predominantly only either said exposed or non-exposed regions, and (2) to provide a protective coating over all of said exposed and non-exposed regions of the resulting first imaged lithographic printing plate, and each of said fresh samples of processing solution are not reused,
C″) repeating steps A and B using a fresh sample of a different processing solution defined in step B for each of one or more additional lithographic printing plate precursors that are different than said one or more precursors defined in A, which fresh samples are not reused.

24. The method of claim 23 wherein said one or more lithographic printing plate precursors imaged and processed in steps A and B are negative-working lithographic printing plate precursors, and said one or more additional lithographic printing plate precursors imaged and processed in step C″ are positive-working lithographic printing plate precursors, or
said one or more lithographic printing plate precursors imaged and processed in steps A and B are positive-working lithographic printing plate precursors, and said one or more additional lithographic printing plate precursors imaged and processed in step C″ are negative-working lithographic printing plate precursors

25. A method of lithographic printing comprising:
A) imagewise exposing a lithographic printing plate precursor comprising a substrate that has a hydrophilic surface using infrared radiation to provide both exposed and non-exposed regions in said imaged precursor,
said lithographic printing plate precursor further comprising an infrared radiation absorbing compound,
B) applying a fresh sample of a processing solution having a pH of from about 6 to about 11 to said imaged precursor both: (1) to remove predominantly only either said exposed regions or said non-exposed regions, and (2) to provide a protective coating over all of the exposed and non-exposed regions of the resulting imaged lithographic printing plate, and said fresh sample of processing solution is not reused,
C) removing excess processing solution from said imaged lithographic printing plate, with optional drying, and
D) contacting said imaged lithographic printing plate with a lithographic printing ink, fountain solution, or both.
